(19) United States
(12) Patent Application Publication
(10) Pub. No.: US 2021/0111364 A1
(43) Pub. Date: Apr. 15, 2021

(54) DISPLAY PANEL AND DISPLAY PANEL MANUFACTURING METHOD

(71) Applicant: JOLED Inc., Tokyo (JP)

(72) Inventors: Koyo SAKAMOTO, Tokyo (JP); Kosuke MISHIMA, Tokyo (JP)

(73) Assignee: JOLED Inc., Tokyo (JP)

(21) Appl. No.: 17/029,062

(22) Filed: Sep. 23, 2020

(30) Foreign Application Priority Data
Sep. 25, 2019 (JP) 2019-174137

(51) Int. Cl. H01L 51/52; H01L 51/56; H01L 51/50

(52) U.S. Cl. CPC H01L 51/5212; H01L 51/524; H01L 51/5092; H01L 51/5056; H01L 51/56

(57) ABSTRACT

A display panel includes: a substrate; anodes that are two-dimensionally disposed on or above the substrate; light-emitting layers that are disposed on or above the anodes in correspondence with the respective anodes; an intermediate layer that is disposed on or above the light-emitting layers and includes a fluoride of a first metal selected from alkali metals or alkaline earth metals; a functional layer that is disposed on the intermediate layer and includes a second metal selected from alkaline earth metals or rare earth metals; a cathode that is disposed on or above the functional layer; a blocking layer that is disposed on or above the cathode and includes a fluoride of a third metal selected from alkali metals or alkaline earth metals; and a sealing layer that is disposed on or above the blocking layer.

This application claims priority to Japanese Patent Application No. 2019-174137, filed Sep. 25, 2019, the contents of which are hereby incorporated by reference in their entirety.

### BACKGROUND

### Technical Field

The present disclosure relates to a display panel in which self-luminous light-emitting elements such as organic electric-field light-emitting elements (referred to hereinafter as organic EL elements) are two-dimensionally arranged across a main surface of a substrate, and to a method of manufacturing the display panel.

### Description of Related Art

As self-luminous displays, organic EL display panels in which organic EL elements are arranged in a matrix on a substrate have been recently put to practical use as displays of electrical equipment.

The organic EL elements each have a basic structure in which an organic light-emitting layer including an organic light-emitting material is disposed between an electrode pair of an anode and a cathode. When driven, a voltage is applied across the electrode pair, and holes injected to the organic light-emitting layer from the anode and electrons injected to the organic light-emitting layer from the cathode recombine to emit light. Thus, the organic EL elements are current-driven light-emitting elements.

Such organic EL display panels typically include an electron transport layer (functional layer) between a cathode and an organic light-emitting layer to improve properties of electron injection from the cathode to the organic light-emitting layer.

For example, Japanese Patent Application Publication No. 2016-115748 (hereinafter referred to as Patent Literature 1) discloses, as the above-mentioned electron transport layer, an organic layer which includes an alkali metal or an alkaline earth metal (hereinafter also referred to simply as, for example, alkali metal or the like, or alkali metal and the like).

Such alkali metals and the like have a low work function and accordingly exhibit properties of injecting and transporting electrons from a cathode, thereby improving luminous efficiency of organic EL elements.

On the other hand, alkali metals and the like have a high chemical activity and accordingly react with impurities such as moisture and gas (especially oxygen) (hereinafter also referred simply to as impurities) included in the organic layer. This deteriorates the electron injection properties and thus shortens an operating life of an organic EL display panel.

In response to this problem, according to the above-mentioned Patent Literature 1, an intermediate layer which includes a fluoride of an alkali metal or the like is disposed between the organic light-emitting layer and the electron transport layer to block impurities intruding from the organic light-emitting layer. This avoids a deterioration in electron injection properties due to reaction of the impurities with the alkali metal or the like included in the electron transport layer.

Also, a sealing layer is disposed above the cathode to prevent intrusion of external impurities into organic EL elements. This also avoids a deterioration of the alkali metal or the like included in the electron transport layer and thus prolongs an operating life of the organic EL elements.

Such a sealing layer is typically a light-transmissive layer which includes silicon nitride (SiN), silicon oxynitride (SiON), or the like (hereinafter, referred collectively to as silicon nitride layer) formed by CVD or the like.

### SUMMARY

A display panel pertaining to at least one aspect of the present disclosure is a display panel including: a substrate; anodes that are two-dimensionally disposed on or above the substrate; light-emitting layers that are disposed on or above the anodes in correspondence with the respective anodes; an intermediate layer that is disposed on or above the light-emitting layers and includes a fluoride of a first metal selected from alkali metals or alkaline earth metals; a functional layer that is disposed on the intermediate layer and includes a second metal selected from alkaline earth metals or rare earth metals; a cathode that is disposed on or above the functional layer; a blocking layer that is disposed on or above the cathode and includes a fluoride of a third metal selected from alkali metals or alkaline earth metals; and a sealing layer that is disposed on or above the blocking layer.

A display panel pertaining to at least one aspect of the present disclosure is a display panel including: a substrate; anodes on or above the substrate so as to be two-dimensionally disposed; light-emitting layers on or above the anodes in correspondence with the respective anodes; a functional layer that is disposed on or above the light-emitting layers and includes a mixture of a fluoride of a first metal selected from alkali metals or alkaline earth metals and a second metal selected from rare earth metals; a cathode that is disposed on or above the functional layer; a blocking layer that is disposed on or above the cathode and includes a fluoride of a third metal selected from alkali metals or alkaline earth metals; and a sealing layer that is disposed on or above the blocking layer.

### BRIEF DESCRIPTION OF THE DRAWINGS

Objects, advantages, and features of the technology pertaining to the present disclosure will become apparent from the following description thereof taken in conjunction with the accompanying drawings, which illustrate at least one embodiment of the technology pertaining to the present disclosure.

FIG. 1 is a block diagram illustrating the overall structure of an organic EL display device pertaining to at least one aspect of the present disclosure.

FIG. 2 is a schematic enlarged plan view illustrating part of an image display surface of an organic EL display panel of the organic EL display device.

FIG. 3 is a schematic cross-section diagram, taken along a line A-A in FIG. 2, illustrating part of the organic EL display panel.

FIG. 4A is a diagram schematically illustrating a layered structure of organic EL elements pertaining to at least one aspect of the present disclosure, and FIG. 4B is a diagram schematically illustrating prevention of external impurity intrusion into a functional layer (Yb-doped layer) by the layered structure.

FIG. 5 is a flowchart illustrating a manufacturing process of the organic EL display panel pertaining to at least one embodiment of the present disclosure.

FIG. 6A to FIG. 6E are partial cross-section diagrams schematically illustrating the manufacturing process of the organic EL display panel.

FIG. 7A to FIG. 7D are partial cross-section diagrams, continuing from FIG. 6E, schematically illustrating the manufacturing process of the organic EL display panel.

FIG. 8A and FIG. 8B are partial cross-section diagrams, continuing from FIG. 7D, schematically illustrating the manufacturing process of the organic EL display panel.

FIG. 9A to FIG. 9D are partial cross-section diagrams, continuing from FIG. 8B, schematically illustrating the manufacturing process of the organic EL display panel.

FIG. 10 is a schematic diagram illustrating a layered structure of organic EL elements pertaining to a first modification in terms of functional layer.

FIG. 11 is a schematic diagram illustrating a layered structure of organic EL elements pertaining to a second modification in terms of functional layer.

FIG. 12 is a schematic diagram illustrating a layered structure of organic EL elements pertaining to a third modification in terms of functional layer.

FIG. 13 is a schematic diagram illustrating a layered structure of organic EL elements pertaining to another modification.

FIG. 14 is a schematic diagram illustrating a layered structure of organic EL elements pertaining to another modification.

FIG. 15 is a schematic diagram illustrating a layered structure of organic EL elements pertaining to another modification.

FIG. 16 is a schematic diagram illustrating a layered structure of organic EL elements pertaining to another modification.

FIG. 17 is a schematic diagram illustrating a layered structure of organic EL elements pertaining to another modification.

FIG. 18 is a schematic diagram illustrating a layered structure of organic EL elements pertaining to another modification.

FIG. 19 is a diagram illustrating an example of a formation range of a block layer in an organic EL display panel pertaining to at least one aspect of the present disclosure.

FIG. 20 is a schematic diagram for explaining a problem which can possibly occur in a layered structure of conventional organic EL elements.

### DETAILED DESCRIPTION

<<Process by which at Least One Aspect of the Present Disclosure was Achieved>>

Conventionally, organic layers included in organic EL display panels have been often formed by a dry process such as vacuum deposition. With a progress of an application technique, especially a printing device technique, a technique of forming organic layers by a wet process has been increasingly widespread in recent years for the following reason.

According to the wet process, an ink containing an organic material dissolved in an organic solvent is printed on a necessary portion by using a printing device or the like, and then the ink is dried. Thus an organic layer is formed. The wet process is excellent in terms of cost for organic EL display panels even with an increased size owing to a suppressed cost of equipment, a high material utilization rate, and the like.

Meanwhile, an electron transport layer which includes an organic material doped with an alkali metal or the like having a low work function is disposed between a cathode and an organic light-emitting layer, such that an excellent carrier balance is maintained to achieve an optimal luminous efficiency of an organic light-emitting layer (for example Patent Literature 1).

However, alkali metals and the like have a high activity and accordingly degrade in reaction with impurities such as moisture and thus might cause a deterioration in electron injection properties. This is a disadvantage of alkali metals and the like.

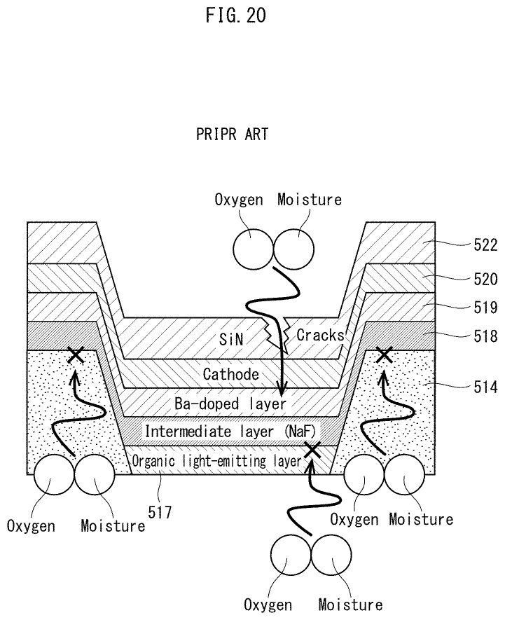

FIG. 20 is a schematic diagram illustrating the outline of a layered structure of the organic EL elements pertaining to the above-mentioned Patent Literature 1, where layers disposed below the organic light-emitting layer are omitted for the purpose of simplification.

As illustrated in the figure, an organic light-emitting layer 517 is disposed in a gap between a pair of banks 514, and an intermediate layer 518 including NaF is disposed between the organic light-emitting layer 517 and a Ba-doped layer (electron transport layer) 519 to suppress intrusion of impurities from the organic light-emitting layer to the electron transport layer. Further, a sealing layer 522 including silicon nitride covers above a cathode 520 to suppress intrusion of external impurities.

Fluorides of alkali metals and the like such as NaF and silicon nitride have excellent properties of blocking impurities, and accordingly suppress intrusion of impurities into the Ba-doped layer 519, thereby promising a prolonged operating life of the organic EL elements.

However, the present inventors' expertise proved the following risk. The sealing layer 522 including silicon nitride is formed by typically CVD or the like. To prevent a heat-induced deterioration of a TFT layer and properties of an organic light-emitting layer of organic EL elements, CVD is performed desirably at a low temperature (for example 80° C.), which deteriorates film denseness of the sealing layer after formation, and in the worst case, foreign substances such as particles (minute clusters of a raw material) or the like might intrude into the sealing layer.

The deterioration of the film denseness might cause intrusion of the impurities into the sealing layer 522 as described above. In addition, intrusion of the foreign substances facilitates generation of cracks in the sealing layer 522. As illustrated in FIG. 20, when the impurities such as moisture intrude into the cracks in the sealing layer 522, Ba included as a dopant in the electron transport layer 519 reacts with the impurities and thus degrades. This deteriorates the electron injection properties and thus shortens the operating life of the organic EL elements.

Such a problem might occur not only in organic EL display panels using organic EL elements as light-emitting elements but also in display panels typically including self-luminous elements and including organic functional layers formed by a wet process such as quantum dot display panels including light-emitting layers which include quantum dot light-emitting diodes (QLEDs).

In view of the problem, the present inventors earnestly conducted researches for seeking a display panel with a prolonged operating life while improving sealing properties against external impurities to exhibit an excellent luminous efficiency. As a result, the present inventors achieved at least one aspect of the present disclosure.

<<Outline of at Least One Aspect of the Present Disclosure>>

A display panel pertaining to at least one aspect of the present disclosure is a display panel including: a substrate; anodes that are two-dimensionally disposed on or above the substrate; light-emitting layers that are disposed on or above the anodes in correspondence with the respective anodes; an intermediate layer that is disposed on or above the light-emitting layers and includes a fluoride of a first metal selected from alkali metals or alkaline earth metals; a functional layer that is disposed on the intermediate layer and includes a second metal selected from alkaline earth metals or rare earth metals; a cathode that is disposed on or above the functional layer; a blocking layer that is disposed on or above the cathode and includes a fluoride of a third metal selected from alkali metals or alkaline earth metals; and a sealing layer that is disposed on or above the blocking layer.

This aspect helps to further suppress intrusion of impurities outside the sealing layer and intrusion of impurities from the light-emitting layer to prevent deterioration of the metal dopant of the functional layer, thereby achieving an excellent luminous efficiency and a prolonged operating life.

Note that an expression “the functional layer includes the second metal” includes a case where the functional layer is a single layer of the second metal.

Also, according to the display panel pertaining to at least one aspect of the present disclosure, the intermediate layer has a film thickness of 0.1 nm to 20 nm.

According to this aspect, the fluoride of the first metal included in the intermediate layer exhibits properties of blocking impurities, and also exhibits the electron injection properties owing to partial reduction exerted by the second metal having reducing properties with which an organic material is doped in the functional layer disposed on the intermediate layer. Thus, a display panel with an excellent luminous efficiency and a long-lasting operating life can be achieved.

Also, according to the display panel pertaining to at least one aspect of the present disclosure, the blocking layer has a film thickness of 0.1 nm to 100 nm.

According to this aspect, the blocking layer exhibits the properties of blocking impurities and maintains a certain level of light-transmissivity so as not to hinder the luminous efficiency.

According to at least one aspect of the present disclosure, the first metal is sodium (Na). Also, according to at least one aspect of the present disclosure, the third metal is sodium (Na).

Fluorides of alkali metals and the like typically have properties of blocking impurities. While many of fluorides of alkali metals and the like are difficult to dissolve in water, NaF is soluble in water and thus absorbs and keeps moisture and the like thereinside. Accordingly, NaF is unlikely to cause a risk that moisture and the like which are blocked and repelled might affect adversely other compositional elements, thereby exhibiting excellent blocking properties compared with other fluorides of alkali metals and the like.

According to at least one aspect of the present disclosure, the second metal is a rare earth metal.

Rare earth metals have a low work function and accordingly exhibit excellent electron injection properties, and also exhibit a chemical stability higher than alkali metals, alkaline earth metals, and the like and thus are difficult to react with impurities such as moisture. Accordingly, even if impurities intrude into the functional layer through the intermediate layer, the blocking layer, or other path, the functional layer can maintain a certain level of electron injection properties for a long time, thereby contributing to further prolonging of the operating life.

According to at least one aspect of the present disclosure, the rare earth metal is ytterbium (Yb).

Yb, among rare earth metals, is excellent in terms of electron injection properties, chemical stability, and reducing properties, and accordingly further contributes to an improvement in luminous efficiency and prolonging of the operating life.

Also, according to at least one aspect of the present disclosure, the functional layer is a single layer of the rare earth metal.

According to this aspect, by forming the functional layer from a single layer of the rare earth metal, the functional layer has an increased effective contact area of the rare earth metal with the fluoride of the first metal included in the intermediate layer. This promotes a reduction action of the fluoride of the first metal exerted by the rare earth metal, thereby helping the first metal obtained by dissociation to improve the electron injection properties.

Also, according to at least one aspect of the present disclosure, the functional layer includes an organic material doped with the rare earth metal.

According to at least one aspect of the present disclosure, a doping concentration of the rare earth metal in the functional layer is 3 wt % to 60 wt %.

According to these aspects, since the doping concentration of the rare earth metal is set to 3 wt % to 60 wt %, required electron injection properties are achieved and a deterioration in light transmittance is suppressed, thereby achieving a desired luminous efficiency.

Also, according to at least one aspect of the present disclosure, the functional layer has a film thickness of 5 nm to 150 nm.

According to this aspect, with the film thickness of 5 nm or larger, the rare earth metal included in the functional layer reduces the fluoride of the first metal included in the intermediate layer to cause dissociation into the first metal, thereby helping the intermediate layer to exhibit the electron injection properties. Also, in the case for example where an ITO film, an IZO film, or the like is formed on the functional layer by sputtering for the purpose of constructing an optical cavity structure, the functional layer relieves sputtering damages so as not to cause damages on the intermediate layer and the light-emitting layer, owing to the film thickness of 5 nm or larger. Meanwhile, with the film thickness of 150 nm or smaller, the functional layer does not cause a risk that the luminous efficiency might be hindered due to a deterioration in light transmittance and light-extraction efficiency.

According to at least one aspect of the present disclosure, a doping concentration of the rare earth metal included in the functional layer continuously increases with increasing proximity to the cathode. Also, according to at least one aspect of the present disclosure, the functional layer includes a first sublayer that is disposed on the intermediate layer and a second sublayer that is disposed on the first sublayer, and the second sublayer includes the rare earth metal at a higher doping concentration than the first sublayer includes.

According to these aspects, portion of the functional layer nearer the intermediate layer is set to include the rare earth metal at a required doping concentration for appropriately reducing the fluoride of the first metal included in the intermediate layer, such that the intermediate layer exhibits the electron injection properties and the blocking properties. Meanwhile, portion of the functional layer nearer the cathode is set to include the rare earth metal at a doping concentration higher than the portion of the functional layer nearer the intermediate layer includes. Thus, the properties of electron injection from the cathode to the functional layer is improved and intrusion of external impurities is prevented, thereby further prolonging the operating life of the display panel. Furthermore, since a magnitude correlation of doping concentration of the rare earth metal is set in a film thickness direction of the functional layer, the total doping amount of the rare earth metal in the functional layer is not excessively required, thereby avoiding an unnecessary deterioration in light-transmissivity.

Also, according to at least one aspect of the present disclosure, the functional layer includes a first sublayer, a second sublayer, and a third sublayer that are layered in this order on the intermediate layer, and a relation X2<X1≤X3 is satisfied, where the first sublayer, the second sublayer, and the third sublayer respectively include the rare earth metal at a doping concentration X1, a doping concentration X2, and a doping concentration X3.

According to this aspect, the concentration of the rare earth metal is set to vary in the film thickness direction of the functional layer. The first sublayer includes the rare earth metal at a doping concentration required for exhibiting the properties of blocking impurities by the fluoride of the first metal included in the intermediate layer and for appropriately reducing the fluoride of the first metal included in the intermediate layer to improve the properties of electron injection to the light-emitting layer. Also, the third sublayer includes the rare earth metal at a high doping concentration, thereby to improve the properties of electron injection from the cathode to the functional layer and prevent intrusion of external impurities. Thus, the operating life of the display panel can be further prolonged. Furthermore, since the second sublayer, which is in the middle between the first sublayer and the third sublayer, includes the rare earth metal at a lower doping concentration than the first and third sublayers, the total doping amount of the rare earth metal in the functional layer is not required excessively, thereby avoiding an unnecessary deterioration in light-transmissivity.

The display panel according to at least one aspect of the present disclosure further includes a light-transmissive and electrically-conductive film that is disposed between the functional layer and the cathode. Also, according to at least one aspect of the present disclosure, the light-transmissive and electrically-conductive film has a film thickness of 15 nm or larger.

According to these aspects, adjustment of the film thickness of the light-transmissive and electrically-conductive film helps to construct an optical cavity structure suitable for wavelength of each light emission color.

The display panel according to at least one aspect of the present disclosure further includes a thin film that is disposed between the functional layer and the light-transmissive and electrically-conductive film, includes a rare earth metal, and has a film thickness of 0.1 nm to 3 nm.

The display panel according to at least one aspect of the present disclosure further includes a thin film that is disposed between the light-transmissive and electrically-conductive film and the cathode, includes a rare earth metal, and has a film thickness of 0.1 nm to 3 nm.

These aspects help to improve film quality of the cathode and prevent intrusion of external impurities, thereby further prolonging the operating life of the display panel.

Also, a display panel pertaining to at least one aspect of the present disclosure is a display panel including: a substrate; anodes on or above the substrate so as to be two-dimensionally disposed; light-emitting layers on or above the anodes in correspondence with the respective anodes; a functional layer that is disposed on or above the light-emitting layers and includes a mixture of a fluoride of a first metal selected from alkali metals or alkaline earth metals and a second metal selected from rare earth metals; a cathode that is disposed on or above the functional layer; a blocking layer that is disposed on or above the cathode and includes a fluoride of a third metal selected from alkali metals or alkaline earth metals; and a sealing layer that is disposed on or above the blocking layer.

According to this aspect, the functional layer includes the mixture of the fluoride of the first metal selected from alkali metals or alkaline earth metals and the second metal selected from rare earth metals. Accordingly, while the properties of blocking impurities are exhibited owing to the fluoride of the first metal, the second metal effectively reduces the fluoride of the first metal to improve the electron injection properties.

Also, according to at least one aspect of the present disclosure, the first metal and the third metal are each sodium (Na), and the second metal is ytterbium (Yb).

NaF exhibits excellent properties of blocking impurities, and Na obtained by dissociation as a result from reduction of NaF exhibits excellent electron injection properties. Also, Yb has a low work function and accordingly exhibits excellent electron injection properties, and also exhibits an excellent chemical stability compared with other rare earth metals and thus is unlikely to react with impurities such as moisture and deteriorate.

The display panel according to at least one aspect of the present disclosure further includes a light-transmissive and electrically-conductive film that is disposed between the functional layer and the cathode so as to be in contact with the functional layer, and includes an inorganic oxide.

According to this aspect, in a display panel forming process, during formation of a light-transmissive and electrically-conductive film including an inorganic oxide on the functional layer, the second metal included in the functional layer is partially oxidized, thereby promising an improvement in light-transmissivity of the functional layer.

The display panel according to at least one aspect of the present disclosure is of a top-emission type.

According to a display panel of the top-emission type, since drive circuits including thin film transistors (TFTs) and so on are not disposed in a light-emitting direction, such that an aperture ratio in each of light-emitting parts is increased and thus an excellent luminous efficiency is exhibited.

A display panel manufacturing method pertaining to at least one aspect of the present disclosure is a method of manufacturing a display panel, the method including: preparing a substrate: forming anodes that are two-dimensionally disposed on or above the substrate; forming light-emitting layers on or above the anodes in correspondence with the respective anodes; forming an intermediate layer on or above the light-emitting layers, the intermediate layer including a fluoride of a first metal selected from alkali metals or alkaline earth metals; forming a functional layer on the intermediate layer, the functional layer including a second metal selected from alkaline earth metals or rare earth metals; forming a cathode on or above the functional layer; forming a blocking layer on or above the cathode, the blocking layer including a fluoride of a third metal selected from alkali metals or alkaline earth metals; and forming a sealing layer on or above the blocking layer.

A display panel manufacturing method pertaining to at least one aspect of the present disclosure is a method of manufacturing a display panel, the method including: preparing a substrate: forming anodes that are two-dimensionally disposed on or above the substrate; forming light-emitting layers on or above the anodes in correspondence with the respective anodes; forming a functional layer on or above the light-emitting layers, the functional layer including a mixture of a fluoride of a first metal selected from alkali metals or alkaline earth metals and a second metal selected from rare earth metals; forming a cathode on or above the functional layer; forming a blocking layer on or above the cathode, the blocking layer including a fluoride of a third metal selected from alkali metals or alkaline earth metals; and forming a sealing layer on or above the blocking layer.

According to this aspect, a display panel with an excellent luminous efficiency and a prolonged operating life can be manufactured as described above.

The method pertaining to at least one aspect of the present disclosure further includes: between the forming the anodes and the forming the light-emitting layers, forming hole transfer facilitating layers that have at least one of hole injection properties and hole transport properties, wherein at least one type of the hole transfer facilitating layers and the light-emitting layers is formed by a wet process.

According to this aspect, even in the case where at least one type of the hole transfer facilitating layers and the light-emitting layers is formed by a wet process for the purpose of reducing manufacturing costs, impurities cannot intrude into the functional layer, and thus a prolonged operating life can be achieved.

Note that in at least one aspect of the present disclosure above, the term “above” does not indicate an upper direction (upward in the vertical direction) in an absolute spatial awareness, but is defined by a relative relationship based on a layering order in a layered structure of the display panel. Specifically, a direction that is perpendicular to the main surface of the substrate and is toward a laminate from the substrate is defined as an upper direction. Also, for example an expression “on the substrate” indicates not only a region in direct contact with the substrate but also an upper region distant from the substrate via the laminate. Further, for example an expression “above the substrate” indicates not only the upper region distant from the substrate via the laminate but also the region in direct contact with the substrate.

### Embodiments

The following describes a display panel pertaining to at least one aspect of the present disclosure by using an example of an organic EL display panel, with reference to the drawings. Note that the drawings may be schematic, and are not necessarily to scale.

1. Overall Structure of Organic EL Display Device 1

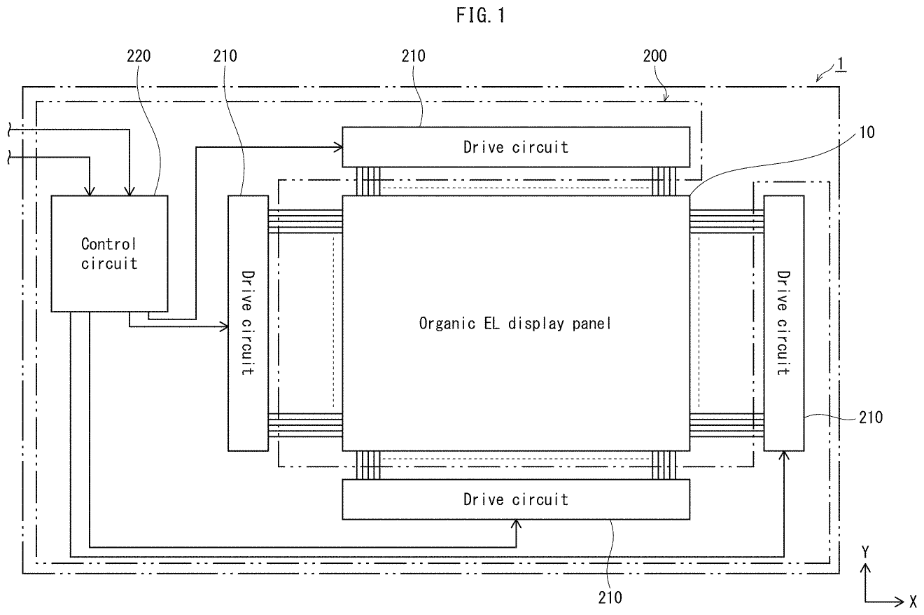

FIG. 1 a block diagram illustrating the overall structure of an organic EL display device 1 in which an organic EL display panel 10 pertaining to at least one aspect of the present disclosure is installed. The organic EL display device 1 is a display device which is used for example for a television, a personal computer, a mobile terminal, or a display for business purposes such as an electronic signboard and a large screen for a commercial facility.

The organic EL display device 1 includes an organic EL display panel 10 and a drive controller 200 which is electrically connected to the organic EL display panel 10.

According to the present embodiment, the organic EL display panel 10 is a top-emission type display panel, a top surface of which is a rectangular image display surface. In the organic EL display panel 10, a plurality of organic EL elements (not illustrated) are arranged across the image display surface, and an image is displayed by combining light emission from the organic EL elements. As an example, the organic EL display panel 10 employs an active matrix system.

The drive controller 200 includes drive circuits 210 connected to the organic EL display panel 10 and a control circuit 220 connected to an external device such as a computer or a receiving device such as an antenna. The drive circuits 210 include power supply circuits supplying electric power to the organic EL elements, signal circuits applying a voltage signal for controlling the electric power supplied to the organic EL elements, a scanning circuit switching a position to which the voltage signal is to be applied at regular intervals, and the like.

The control circuit 220 controls operations of the drive circuits 210 in accordance with data including image information input from the external device or the receiving device.

In FIG. 1, as an example, four of the drive circuits 210 are disposed around the organic EL display panel 10, but the structure of the drive controller 200 is not limited to this example, and the number and position of the drive circuits 210 may be modified as appropriate. Also, for the sake of explanation, as illustrated in FIG. 1, a direction along a long side of the top surface of the organic EL display panel 10 is referred to as X direction and a direction along a short side of the top surface of the organic EL display panel 10 is referred to as Y direction.

2. Structure of Organic EL Display Panel 10

(A) Plan View Structure

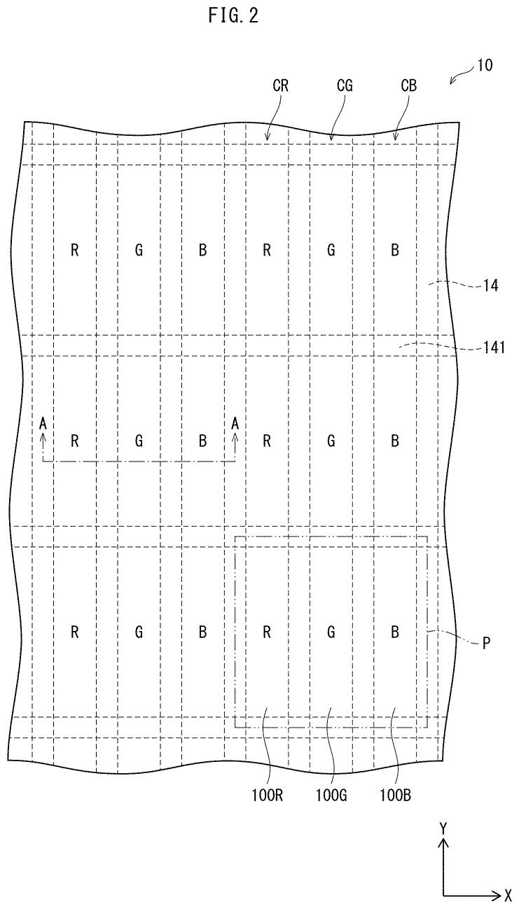

FIG. 2 is a schematic enlarged plan view illustrating part of the image display surface of the organic EL display panel 10. According to the organic EL display panel 10, as an example, subpixels 100R, 100G, and 100B are arranged in a matrix. The subpixels 100R, 100G, and 100B respectively emit light of red color (R), green color (G), and blue color (B) (hereinafter also referred to simply as R, G, and B). The subpixels 100R, 100G, and 100B are lined up alternating in the X direction, and a set of the subpixels 100R, 100G, and 100B arranged in the X direction constitute one pixel P. In one pixel P, full color can be expressed by combining gradation-controlled emission luminance of the subpixels 100R, 100G, and 100B.

In addition, in the Y direction, the subpixels 100R, 100G, and 100B are arranged to form subpixel columns CR, CG, and CB, respectively, in which only the corresponding color of subpixels are present. As a result, across the organic EL display panel 10, the pixels P are arranged in a matrix along the X direction and the Y direction, and an image is displayed on the image display surface through a combination of colors of light emitted by the pixels P.

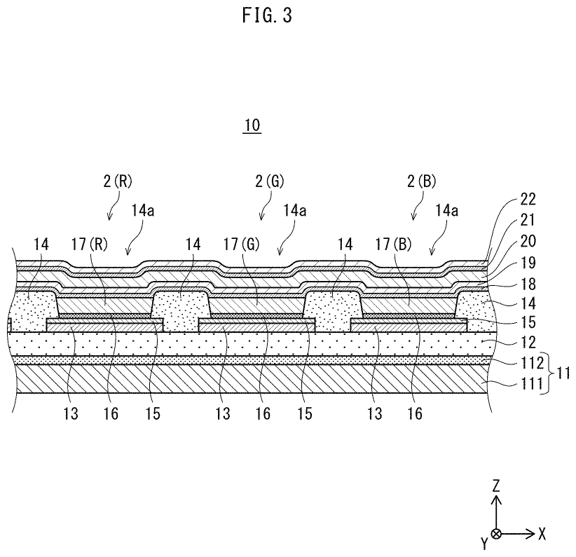

In the subpixels 100R, 100G, and 100B, the organic EL elements 2(R), 2(G), and 2(B), which respectively emit light of the R, G, and B colors, are respectively arranged (see FIG. 3).

Also, the organic EL display panel 10 pertaining to the present embodiment employs a so-called line bank structure. In other words, the subpixel columns CR, CG, and CB are partitioned by banks 14 at intervals in the X direction, and in each of the subpixel columns CR, CG, and CB, the subpixels 100R, 100G, or 100B therein share a continuous organic light-emitting layer.

However, in each of the subpixel columns CR, CG, and CB, pixel partition layers 141 are disposed at intervals in the Y direction to insulate the subpixels 100R, 100G, and 100B from each other, such that each of the subpixels 100R, 100G, and 100B can emit light independently.

Note that the pixel partition layers 141 have a height lower than a height of liquid surfaces of an ink applied for organic light-emitting layer formation. In FIG. 2, the banks 14 and the pixel partition layers 141 are indicated by dotted lines. This is because the banks 14 and the pixel partition layers 141 are not exposed on the surface of the image display surface and are disposed under the image display surface.

(B) Cross-Section Structure

FIG. 3 is a schematic cross-section diagram taken along a line A-A in FIG. 2.

The display panel 10 includes pixels which are each composed of three subpixels each emitting light of a different one of the R, G, and B colors. The three subpixels, namely the subpixels 100R, 100G, and 100B are respectively composed of organic EL elements 2(R), 2(G), and 2(B) emitting light of a corresponding color.

The organic EL elements 2(R), 2(G), and 2(B), which respectively emit light of the R, G, and B colors, basically have the same structure, and thus are referred collectively to as organic EL elements 2 when they are not distinguished from each other.

As illustrated in FIG. 3, the organic EL elements 2 include a substrate 11, an interlayer insulating layer 12, pixel electrodes (anodes) 13, banks 14, hole injection layers 15, hole transport layers 16, organic light-emitting layers 17, an intermediate layer 18, a functional layer 19, a counter electrode (cathode) 20, a blocking layer 21, and a sealing layer 22.

The substrate 11, the interlayer insulating layer 12, the intermediate layer 18, the functional layer 19, the counter electrode 20, the blocking layer 21, and the sealing layer 22 are disposed not for each pixel but across all the organic EL elements 2 included in the organic EL display panel 10. In at least one embodiment, the intermediate layer 18, the functional layer 19, the counter electrode 20, and so on are each formed separately for each subpixel or for each pixel.

(1) Substrate

The substrate 11 includes a base material 111 which is an insulating material and a TFT layer 112. The TFT layer 112 has a driving circuit formed therein for each subpixel. The base material 111 is for example a glass substrate, a quartz substrate, a silicon substrate, or a metal substrate including molybdenum sulfide, copper, zinc, aluminum, stainless, magnesium, iron, nickel, gold, and silver, a semiconductor substrate including gallium arsenide, or a plastic substrate.

Either thermoplastic resin or thermosetting resin is usable as a material of the plastic substrate, including polyethylene, polypropylene, polyamide, polyimide (PI), polycarbonate, acrylic resin, polyethylene terephthalate (PET), polybutylene terephthalate, polyacetal, other fluororesin, thermoplastic elastomer such as styrene elastomer, polyolefin elastomer, polyvinyl chloride elastomer, polyurethane elastomer, fluorine rubber elastomer, and chlorinated polyethylene elastomer, epoxy resin, unsaturated polyester, silicone resin, polyurethane, or copolymer, blend, polymer alloy or the like mainly including such a material described above. The plastic substrate may be a laminate of any one type or any two or more types of the materials described above.

(2) Interlayer Insulating Layer

The interlayer insulating layer 12 is disposed on the substrate 11. The interlayer insulating layer 12 includes a resin material and is provided for flattening unevenness of a top surface of the TFT layer 112. The resin material is for example a positive photosensitive material. Examples of the photosensitive material include acrylic resin, polyimide resin, siloxane resin, and phenolic resin. Also, although not illustrated in the cross-section in FIG. 3, the interlayer insulating layer 12 has a contact hole provided therein for each subpixel.

(3) Pixel Electrodes

The pixel electrodes 13 include metal layers including a light-reflective metal material, and are disposed on the interlayer insulating layer 12. The pixel electrode 13 is formed for each subpixel, and is electrically connected with the TFT layer 112 via a contact hole (not illustrated).

In the present embodiment, the pixel electrode 13 functions as an anode.

Specific examples of the light-reflective metal material include silver (Ag), aluminum (Al), alloy of aluminum, molybdenum (Mo), alloy of silver, palladium, and copper (APC), alloy of silver, rubidium, and gold (ARA), alloy of molybdenum and chromium (MoCr), alloy of molybdenum and tungsten (MoW), and alloy of nickel and chromium (NiCr).

In at least one embodiment, the pixel electrodes 13 are single metal layers. In at least one embodiment, the pixel electrodes 13 have a layered structure including a metal oxide layer such as an indium tin oxide (ITO) layer or an indium zinc oxide (IZO) layer layered on a metal layer.

(4) Banks and Pixel Partition Layers

The banks 14 partition the pixel electrodes 13 corresponding one-to-one to the subpixels above the substrate 11 into columns in the X direction (see FIG. 2), and each have a line bank shape extending in the Y direction between the subpixel columns CR, CG, and CB in the X direction.

An electrically-insulating material is used for the banks 14. Specific examples of the electrically-insulating material include an insulating organic material such as acrylic resin, polyimide resin, novolac resin, and phenolic resin.

The banks (column banks) 14 function as structures for preventing an ink mixture between subpixels in each pixel when the organic light-emitting layers 17 are formed by an application method.

When a resin material is used for the banks 14, a photosensitive resin material is preferable from the viewpoint of processability. Photosensitivity of the resin material may be either positive or negative.

In at least one embodiment, the banks 14 are resistant to organic solvents and heat. Also, in at least one embodiment, surfaces of the banks 14 have liquid-repellency to suppress an ink overflow.

Where the pixel electrodes 13 are not formed, bottom surfaces of the banks 14 are in contact with a top surface of the interlayer insulating layer 12.

The pixel partition layers (row banks) 141 include an electrically-insulating material, and cover end portions in the Y direction (FIG. 2) of the pixel electrodes 13 in each sub pixel column, partitioning the pixel electrodes 13 in the Y direction.

Film thickness of the pixel partition layers 141 is set to be slightly larger than film thickness of the pixel electrodes 13 but height of top surfaces of the pixel partition layers 141 is set to be smaller than height of top surfaces of the organic light-emitting layers 17. Thus, the organic light-emitting layers 17 in the subpixel columns CR, CG, and CB are not partitioned by the pixel partition layers 141, and accordingly an ink flow is not disturbed when forming the organic light-emitting layers 17. This facilitates the film thickness of each of the organic light-emitting layers 17 to be uniform within the corresponding subpixel column.

With the structure described above, the pixel partition layers 141 improve electrical insulation between the pixel electrodes 13 in the Y direction and also have functions of suppressing discontinuity of the organic light-emitting layers 17 within any of the subpixel columns CR, CG, and CB, improving electrical insulation between the pixel electrodes 13 and the counter electrode 20, and so on.

Specific examples of the electrically-insulating material used for the pixel partition layers 141 include a resin material exemplified as the material of the banks 14 and an inorganic material. Also, in at least one embodiment, surfaces of the pixel partition layers 141 have lyophilic properties with respect to an ink in order to facilitate an ink spreading when forming the organic light-emitting layers 17 which are to be upper layers of the pixel partition layers 141.

(5) Hole Injection Layers

The hole injection layers 15 are disposed on the pixel electrodes 13 to promote injection of holes from the pixel electrodes 13 to the organic light-emitting layers 17. The hole injection layers 15 are layers which include for example an oxide of a metal such as silver (Ag), molybdenum (Mo), chromium (Cr), vanadium (V), tungsten (W), nickel (Ni), and iridium (Ir), or an electrically-conductive polymer material such as poly(3,4-ethylenedioxythiophene) polystyrene sulfonate (PEDOT:PSS). The hole injection layers 15 can be formed by for example a sputtering process or a wet process.

In the case where any of the above-mentioned metal oxides is used, the hole injection layers 15 have a high work function and thus stably inject holes to the organic light-emitting layers 17.

(6) Hole Transport Layers

The hole transport layers 16 have a function of transporting holes injected from the hole injection layers 15 to the organic light-emitting layers 17. The hole transport layers 16 are formed by a wet process using for example a high-molecular compound having no hydrophilic group such as polyfluorene, a polyfluorene derivative, polyallylamine, and a polyallylamine derivative.

(7) Organic Light-Emitting Layers

The organic light-emitting layers 17 are disposed inside the openings 14a, and each have a function of emitting light of R, G, or B color owing to recombination of holes and electrons. Particularly when it is necessary to specify the light emission color for explanation, the organic light-emitting layers 17 are referred to as the organic light-emitting layers 17(R), 17(G), and 17(B) separately.

Publicly-known materials are usable for a material of the organic light-emitting layers 17. Specific examples of the material of the organic light-emitting layers 17 include phosphor such as an oxinoid compound, a perylene compound, a coumarin compound, an azacoumarin compound, an oxazole compound, an oxadiazole compound, a perinone compound, a pyrrolopyrrole compound, a naphthalene compound, an anthracene compound, a fluorene compound, a fluoranthene compound, a tetracene compound, a pyrene compound, a coronene compound, a quinolone compound and an azaquinolone compound, a pyrazoline derivative and a pyrazolone derivative, a rhodamine compound, a chrysene compound, a phenanthrene compound, a cyclopentadiene compound, a stilbene compound, a diphenylquinone compound, a styryl compound, a butadiene compound, a dicyanomethylenepyran compound, a dicyanomethylenethiopyran compound, a fluorescein compound, a pyrylium compound, a thiapyrylium compound, a selenapyrylium compound, a telluropyrylium compound, an aromatic aldadiene compound, an oligophenylene compound, a thioxanthene compound, a cyanine compound, an acridine compound, and a metal complex of an 8-hydroxyquinoline compound, a metal complex of a 2-bipyridine compound, a complex of a Schiff base and a group III metal, an oxine metal complex, and a rare earth complex.

(8) Intermediate Layer

The intermediate layer 18 has a function of suppressing movement of impurities from the organic layers provided thereunder to the functional layer 19, and a function of transporting electrons from the counter electrode 20 to the organic light-emitting layers 17. In the present embodiment, the intermediate layer 18 includes sodium fluoride (NaF) for the following reasons. NaF has properties of blocking impurities such as moisture, and also excellent electron injection properties owing to dissociation of Na are exhibited by layering a material which has reducibility as an upper layer of the intermediate layer 18.

(9) Functional Layer

The functional layer 19 has a function of injecting and transporting electrons supplied from the counter electrode 20 toward the organic light-emitting layers 17. The functional layer 19 includes an organic material, in particular, an organic material having electron transport properties, doped with ytterbium (Yb).

The organic material (host material) having electron transport properties is for example a π-electron low molecular organic material such as an oxadiazole derivative (OXD), a triazole derivative (TAZ), and a phenanthroline derivative (BCP, Bphen), but is not limited to these materials.

(10) Counter Electrode

The counter electrode 20 includes a light-transmissive and electrically-conductive material, and is disposed on the functional layer 19. The counter electrode 20 functions as a cathode.

A metal thin film or a light-transmissive and electrically-conductive film of ITO, IZO, AZO, or the like is usable as the counter electrode 20. In the present embodiment, to obtain an optical cavity structure further effectively, the counter electrode 20 should preferably be a metal thin film including at least one material selected from the group consisting of aluminum, magnesium, silver, aluminum-lithium alloy, magnesium-silver alloy, and the like. In at least one embodiment, the metal thin film in this case has a film thickness of 5 nm to 30 nm so as to have light-semitransmissivity (half mirror structure).

(11) Blocking Layer

The blocking layer 21 is provided for blocking intrusion of external impurities. If the sealing layer 22 has cracks and impurities intrude through the cracks, the blocking layer 21 suppresses intrusion of impurities into the functional layer 19.

A preferable material of the blocking layer 21 is a fluoride of a metal selected from alkali metals or alkaline earth metals, which is light-transmissive and has excellent properties of blocking impurities.

In the present embodiment, the blocking layer 21 includes NaF which is the same as in the intermediate layer 18.

(12) Sealing Layer

The sealing layer 22 is provided for preventing organic layers including the hole transport layers 16, the organic light-emitting layers 17, the functional layer 19 from being exposed to external impurities and thus from being deteriorated.

The sealing layer 22 includes a light-transmissive material such as silicon nitride (SiN) or silicon oxynitride (SiON).

(13) Others

In at least one embodiment, although not illustrated in FIG. 3, an antiglare polarizing plate or an upper substrate is attached onto the sealing layer 22 via a light-transmissive adhesive. Also, in at least one embodiment, a color filter substrate is attached onto the sealing layer 22 so as to correct chromaticity of light emitted from the organic EL elements 2. Attachment of such a substrate or the like helps to further protect the hole transport layers 16, the organic light-emitting layers 17, the functional layer 19, and so on against external impurities.

3. Layered Structure of Organic EL Elements and Effects Thereof

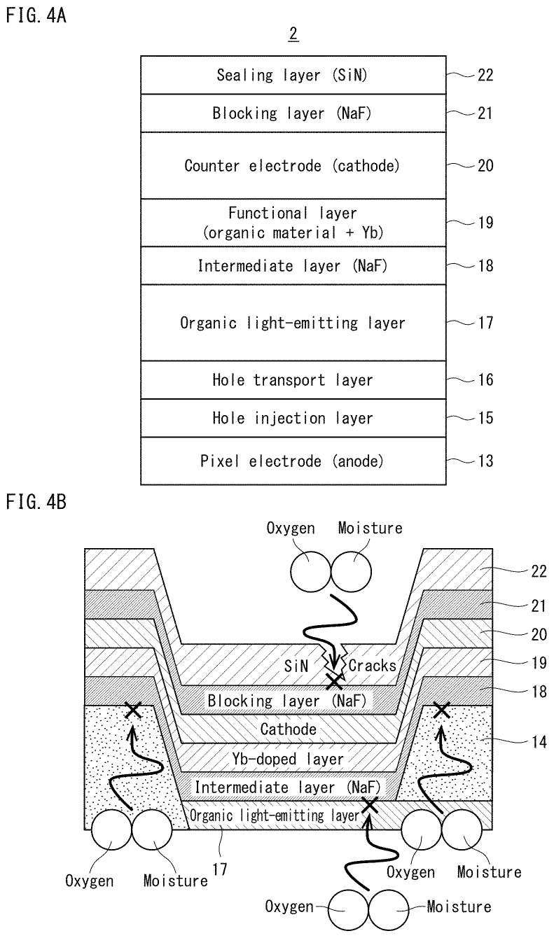

(1) FIG. 4A is a diagram for easy understanding which schematically illustrates a layered structure including ever layer from the pixel electrodes (anodes) 13 to the sealing layer 22 in the organic EL elements 2 of the above-mentioned organic EL display panel 10. FIG. 4B is a cross-section diagram schematically illustrating prevention of intrusion of external impurities such as moisture into the functional layer 19. Note that layers disposed under the organic light-emitting layers 17 are omitted in FIG. 4B for simplification.

As illustrated in FIG. 4A, the intermediate layer 18, which includes NaF having high properties of blocking impurities, is disposed under the functional layer 19, and the blocking layer 21, which includes NaF likewise, is disposed between the counter electrode 20 and the sealing layer 22. Also, the functional layer 19 includes an organic material doped with Yb.

As illustrated in FIG. 4B, the intermediate layer 18, which is disposed under the functional layer 19, covers both the top surfaces of the organic light-emitting layers 17 and the banks 14. With this structure, in the case where a wet process is used for forming the organic light-emitting layers 17 and at least one of the hole injection layers 15 and the hole transport layers 16, which are disposed under the organic light-emitting layers 17, the intermediate layer 18 can prevent intrusion of impurities such as moisture into the functional layer 19 if the impurities remain in these layers.

Further, the blocking layer 21, which includes NaF likewise, is disposed on the counter electrode 20. With this structure, if the sealing layer 22 has cracks and external impurities intrude through the cracks, the blocking layer 21 can block the impurities, thereby preventing further intrusion of the impurities into the counter electrode 20 and the functional layer 19, which are disposed under the blocking layer 21.

In this way, the intermediate layer 18 and the blocking layer 21, which include NaF having the properties of blocking impurities, sandwich the functional layer 19 therebetween to protect the functional layer 19. With this structure having a combined effect of the intermediate layer 18 and the blocking layer 21, a deterioration of electron injection properties of the metal dopant of the functional layer 19 is significantly suppressed. Thus, a prolonged operating life of the organic EL elements 2 can be achieved.

(2) Moreover, in the present embodiment, as the metal dopant of the functional layer 19, ytterbium (Yb) which is a rare earth metal is adopted, unlike conventional adoption of Ba which is an alkaline earth metal.

The host organic material of the functional layer 19 is selected from known organic materials having any one of electron transport properties, electron injection properties, and electron injection transport properties.

Yb belongs to rare earth metals, and has a work function as low as conventionally adopted Ba belonging to alkaline earth metals, and thus exhibits excellent electron injection properties in itself, and also has reducing properties. Thus, Yb reduces a fluoride of an alkali metal or the like included in the intermediate layer 18 to cause dissociation, thereby exhibits the electron injection properties which are inherent in the alkali metal or the like to contribute to an improvement in luminous efficiency.

In addition, the researches made by the present inventors demonstrated the following features of rare earth metals, especially Yb: (A) a low reactivity with impurities; and (B) a high light transmittance, compared with alkaline earth metals. Owing to these features, further excellent organic EL elements can be obtained.

Specifically, owing to the feature (A) of Yb having a low reactivity with impurities, even if impurities intrude into the functional layer 19 because of being incompletely blocked by the intermediate layer 18 and the blocking layer 21, the electron injection properties of the functional layer 19 are unlikely to deteriorate. This further prolongs the operating life of the organic EL elements. Also, owing to the feature (B) of Yb having a high light transmittance, light-extraction efficiency is improved compared with the case where an alkaline earth metal such as Ba is used.

Thus, with the structure in the present embodiment, while the manufacturing costs can be reduced by using a wet process for forming, as an applied film, at least one type of the hole injection layers 15, the hole transport layers 16, and the organic light-emitting layers 17, and the like of the organic EL elements 2, impurities remaining in the applied film and externally intruding impurities can be blocked to suppress a deterioration of the electron injection properties of the functional layer 19 as much as possible. Thus, the operating life of the organic EL elements 2 can be significantly prolonged.

4. Film Thickness of Intermediate Layer, Functional Layer, and Blocking Layer and Doping Concentration in Functional Layer

(1) Film Thickness of Intermediate Layer

The intermediate layer 18 includes NaF which exhibits properties of electron injection to the organic light-emitting layers 17 and the properties of blocking impurities, as described above. In view of this, in at least one embodiment, the intermediate layer 18 has a film thickness of 0.1 nm to 20 nm for the following reasons.

With an excessively thin film thickness smaller than 0.1 nm, the intermediate layer 18 cannot sufficiently exhibit effects of the properties of electron injection to the organic light-emitting layers 17 and the properties of blocking impurity intrusion into the functional layer 19. Also, with a film thickness larger than 20 nm, the intermediate layer 18 has electron injection properties deteriorated due to an insufficient reduction action on the inside of the intermediate layer 18 exerted by the metal dopant of the functional layer 19.

(2) Film Thickness of Functional Layer

The functional layer 19 includes, as its metal dopant, Yb which has excellent properties of electron injection from the counter electrode 20 functioning as a cathode and a high light-transmissivity compared with conventional Ba and the like. In view of this, in at least one embodiment, the functional layer 19 has a film thickness of 5 nm to 150 nm for the following reasons.

With an extremely thin film thickness smaller than 5 nm, the functional layer 19 cannot reduce NaF included in the intermediate layer 18 enough, and thus a sufficient electron injection from the counter electrode 20 cannot be obtained. Also, with a film thickness larger than 150 nm, the functional layer 19 deteriorates the light transmittance and thus deteriorates the light-extraction efficiency and as a result might interfere with the luminous efficiency.

Since the film thickness of the functional layer 19 can be set within a broad range from 5 nm to 150 nm in this way, an optical cavity structure, especially a secondary cavity, can be easily constructed within this film thickness range by optical design.

The intermediate layer 18 simultaneously exhibits the two functions, namely, the function of blocking movement of impurities from the organic layers provided thereunder to the functional layer 19 and the function of electron injection to the organic light-emitting layers 17. Taking this into consideration, it is effective that the intermediate layer 18 is layered directly on the organic light-emitting layers 17 and the functional layer 19 is layered directly on the intermediate layer 18 so as to be contact in the intermediate layer 18.

(3) Doping Concentration of Yb in Functional Layer

In at least one embodiment, the doping concentration of Yb included in the functional layer 19 ranges from 3 wt % to 60 wt % for the following reasons. With a doping concentration smaller than 3 wt %, the functional layer 19 cannot achieve required electron injection properties. Also, with a doping concentration larger than 60 wt %, the functional layer 19 deteriorates the light-transmissivity and thus might deteriorate the luminous efficiency.

Note that in the case where Ba is used as the metal dopant as in a conventional manner, its preferable doping concentration has been considered to range from 5 wt % to 40 wt %. Although Yb and Ba have substantially equal electron injection properties, the lower limit of doping concentration of Yb can be set lower than that of Ba. This is because Yb has a lower reactivity with impurities such as moisture than Ba, and accordingly the functional layer 19 including Yb even at a low doping concentration can exhibit a certain level of electron injection properties for a long time. In addition, Yb has a more excellent light-transmissivity than Ba, and accordingly the upper limit of doping concentration of Yb can be set higher than that of Ba, thereby increasing the effect of the properties of electron injection from the counter electrode 20 than Ba.

(4) Film Thickness of Blocking Layer

In at least one embodiment, the blocking layer 21 has a film thickness of 0.1 nm to 100 nm for the following reasons.

Similarly to the intermediate layer 18, with an excessively thin film thickness smaller than 0.1 nm, the blocking layer 21 cannot sufficiently exhibit an effect of the properties of blocking impurities. Also, with a film thickness larger than 100 nm, the blocking layer 21 deteriorates the light transmittance and thus might interfere with the luminous efficiency. Further, in at least one embodiment, the blocking layer 21 has a film thickness of 0.1 nm to 20 nm. Since the film thickness of the blocking layer 21 can be set within a relatively broad range in this way, cavity design is easily performed in construction of an optical cavity structure.

5. Method of Manufacturing Organic EL Display Panel 10

The following describes a method of manufacturing the organic EL display panel 10, pertaining to at least one aspect of the present disclosure, with reference to the drawings.

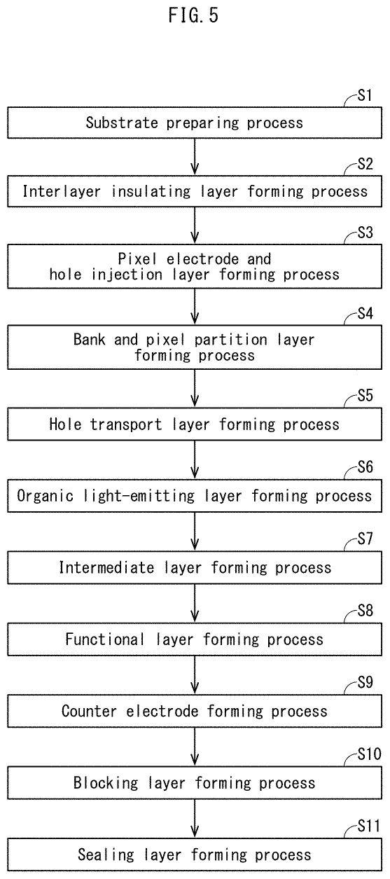

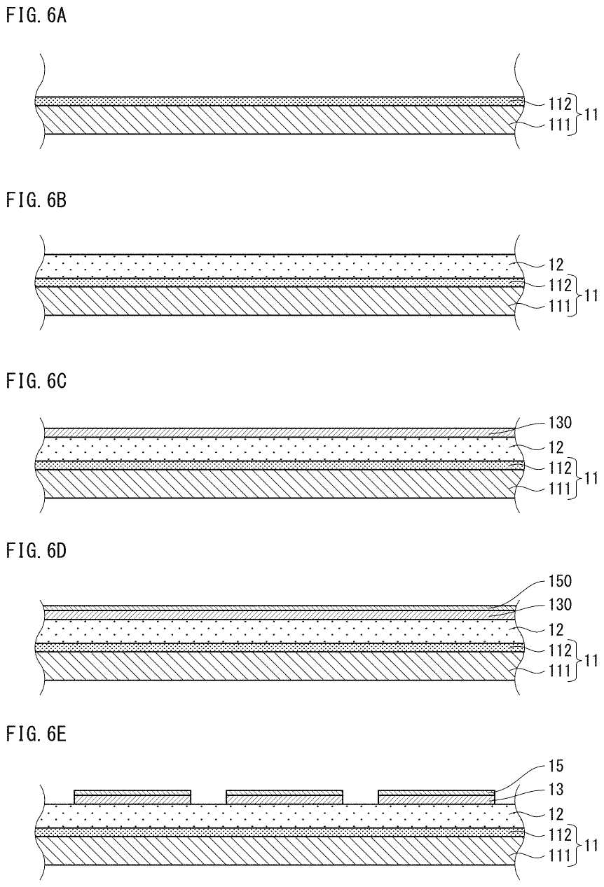

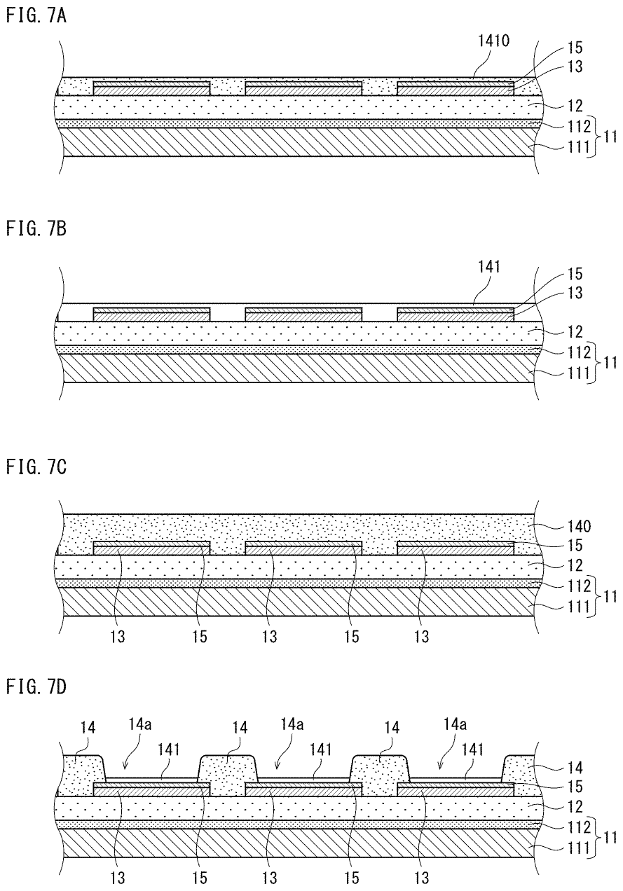

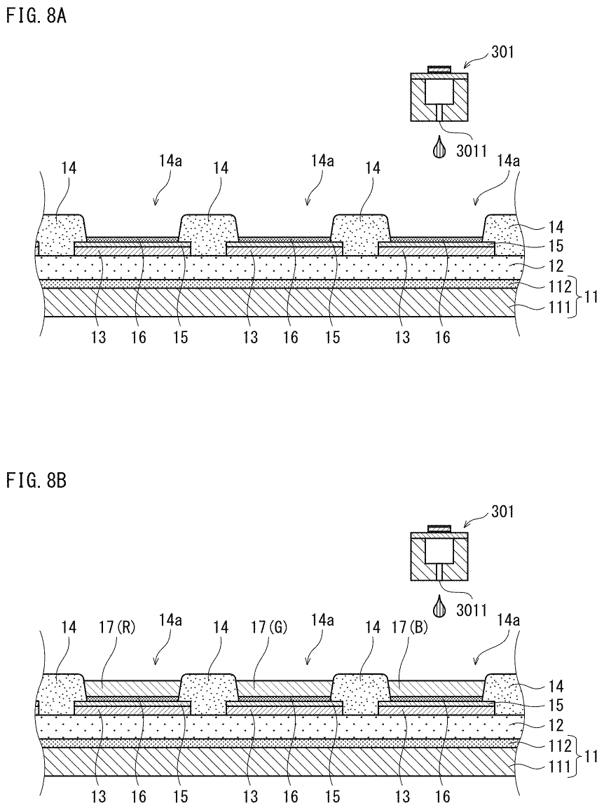

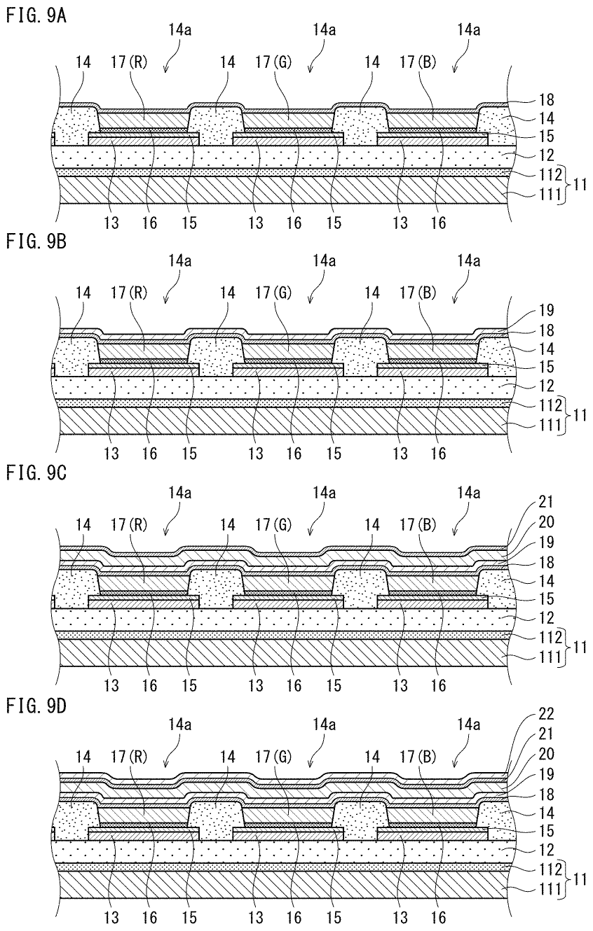

FIG. 5 is a flowchart illustrating a manufacturing process of the organic EL display panel 10. FIG. 6A to FIG. 6E, FIG. 7A to FIG. 7D, FIG. 8A and FIG. 8B, and FIG. 9A to FIG. 9D are schematic cross-section diagrams illustrating processes in manufacturing the organic EL display panel 10.

(1) Substrate Preparing Process

First, as illustrated in FIG. 6A, a substrate 11 is prepared by forming a TFT layer 112 on a base material 111 (FIG. 5: Step S1). The TFT layer 112 can be formed by a known TFT manufacturing method.

(2) Interlayer Insulating Layer Forming Process

Next, as illustrated in FIG. 6B, an interlayer insulating layer 12 is formed on the substrate 11 (FIG. 5: Step S2).

Specifically, a resin material having a certain fluidity is applied across a top surface of the substrate 11 by for example die coating so as to fill irregularities in the substrate 11 caused by the TFT layer 112. Thus, a top surface of the interlayer insulating layer 12 has a flattened shape along a top surface of the base material 111.

Also, dry-etching is performed on portions of the interlayer insulating layer 12 above TFT elements, for example source electrodes thereof, to provide contact holes (not illustrated). The contact holes are provided by patterning or the like such that surfaces of the source electrodes are exposed at bottoms of the contact holes.

Next, connection electrode layers are formed along inner walls of the contact holes. Upper portions of the connection electrode layers are partially disposed on the interlayer insulating layer 12. The connection electrode layers can be formed by forming a metal film by for example sputtering, and then patterning the metal film by photolithography and wet etching.

(3) Pixel Electrode and Hole Injection Layer Forming Process

Next, as illustrated in FIG. 6C, a pixel electrode material layer 130 is formed on the interlayer insulating layer 12. The pixel electrode material layer 130 can be formed by vacuum deposition, sputtering, or the like.

Further, a hole injection material layer 150 is formed on the pixel electrode material layer 130 (FIG. 6D). The hole injection material layer 150 can be formed by reactive sputtering or the like.

Then, as illustrated in FIG. 6E, the pixel electrode material layer 130 and the hole injection material layer 150 are patterned by etching to form pixel electrodes 13 and hole injection layers 15 which are partitioned for each subpixel (FIG. 5: Step S3).

Methods of forming the pixel electrodes 13 and the hole injection layers 15 are not limited to the above-mentioned methods. In at least one embodiment, after the pixel electrodes 13 are formed by patterning the pixel electrode material layer 130, the hole injection layers 15 is formed. Also, in at least one embodiment, after the banks 14 are formed, the hole injection layers 15 are formed by a printing method.

(4) Bank and Pixel Partition Layer Forming Process

Next, banks 14 and pixel partition layers 141 are formed (FIG. 5: Step S4).

In the present embodiment, the pixel partition layers 141 and the banks 14 are formed through separate processes.

(4-1) Pixel Partition Layer Forming Process

First, the pixel partition layers 141 extending in the X direction are formed so as to partition pixel electrode columns extending in the Y direction (FIG. 2) for each subpixel.

As illustrated in FIG. 7A, a pixel partition material layer 1410 is formed by uniformly applying a photosensitive resin material which is a material of the pixel partition layers 141 onto the interlayer insulating layer 12 on which the pixel electrodes 13 and the hole injection layers 15 are formed, such that the pixel partition material layer 1410 after drying has a film thickness equal to a desired height of the pixel partition layers 141.

A method of applying the resin material is specifically for example a wet process such as die coating, slit coating, and spin coating. In at least one embodiment, by for example vacuum drying and low-temperature heating at an approximate temperature of 60° C. to 120° C. (pre-baking) after application, an unnecessary solvent is removed, and also the pixel partition material layer 1410 is fixed onto the interlayer insulating layer 12.

Then, the pixel partition material layer 1410 is patterned by photolithography.

For example, in the case where the pixel partition material layer 1410 has positive photosensitivity, exposure is performed on the pixel partition material layer 1410 via a photomask (not illustrated). The photomask shields portions of the pixel partition material layer 1410 to remain as the pixel partition layers 141 against light, and has light-transmissive portions corresponding to portions of the pixel partition material layer 1410 to be removed.

Next, developing is performed, and the exposed portions of the pixel partition material layer 1410 are removed, completing the pixel partition layers 141. Specific examples of developing methods include a method of immersing the whole substrate 11 in a developer such as an organic solvent and an alkali solution which dissolves portions of the pixel partition material layer 1410 which have been exposed to light, and then rinsing the substrate 11 by a rinse solution such as pure water.

Then, the pixel partition material layer 1410 is baked (post-baked) at a predefined temperature. As a result, the pixel partition layers 141 extending in the X direction are formed on the interlayer insulating layer 12 (FIG. 7B).

(4-2) Bank Forming Process

Next, the banks 14 extending in the Y direction are formed in the same manner as the pixel partition layers 141 described above.

Specifically, a bank material layer 140 is formed by applying a resin material for banks by die coating or the like onto the interlayer insulating layer 12, on which the pixel electrodes 13, the hole injection layers 15, and the pixel partition layers 141 are formed, such that the bank material layer 140 after drying has a film thickness equal to a desired height of the banks 14 (FIG. 7C). Then, the bank material layer 140 is patterned to make the banks 14 extending in the Y direction by photolithography and is baked at a predefined temperature, completing the banks 14 (FIG. 7D).

In the above-mentioned process, the respective material layers for the pixel partition layers 141 and the banks 14 are both formed by a wet process and then are patterned. At least one type of the respective material layers for the pixel partition layers 141 and the banks 14 may be formed by a dry process and then be patterned by photolithography and etching.

(5) Hole Transport Layer Forming Process

Next, as illustrated in FIG. 8A, an ink containing a material of the hole transport layers 16 is ejected from nozzles 3011 of an application head 301 of a printing device into openings 14a defined by the banks 14, so as to be applied onto the hole injection layers 15 in the openings 14a (printing method). At this time, the ink is applied so as to extend above the pixel electrode columns in the Y direction (FIG. 2). Then, the ink is dried. Thus, the hole transport layers 16 is completed (FIG. 5: Step S5).

(6) Organic Light-Emitting Layer Forming Process

Next, organic light-emitting layers 17 are formed above the hole transport layers 16 (FIG. 5: Step S6).

Specifically, as illustrated in FIG. 8B, an ink containing a light-emitting material of a corresponding light emission color is sequentially ejected from the nozzles 3011 of the application head 301 of the printing device into the openings 14a, so as to be applied onto the hole transport layers 16 in the openings 14a. At this time, the ink is applied so as to be continuous above the pixel partition layers 141 as well as on the hole transport layers 16. This enables the ink to flow in the Y direction, and thus liquid surfaces of the ink are levelled and application unevenness of the ink is eliminated. Thus, the organic light-emitting layers 17 can be formed so as to have a uniform film thickness within each subpixel column.

Then, the substrate 11 after ink application is carried into a vacuum dry chamber and is heated in a vacuum, thereby evaporating an organic solvent in the ink. Thus, the organic light-emitting layers 17 are completed.

(7) Intermediate Layer Forming Process

Next, as illustrated in FIG. 9A, an intermediate layer 18 is formed on the organic light-emitting layers 17 and the banks 14 (FIG. 5: Step S7). The intermediate layer 18 is formed by forming a film of NaF across all the subpixels by vapor deposition.

(8) Functional Layer Forming Process

Next, as illustrated in FIG. 9B, a functional layer 19 is formed on the intermediate layer 18 (FIG. 5: Step S8). The functional layer 19 is formed by for example forming a film using an organic material having electron transport properties and Yb as a metal dopant across all the subpixels by co-deposition.

(9) Counter Electrode Forming Process

Next, a counter electrode 20 is formed on the functional layer 19 across all the subpixels (FIG. 5: Step S9). In the present embodiment, the counter electrode 20 is formed by forming a film of silver, aluminum, or the like by sputtering, vacuum deposition, or the like.

(10) Blocking Layer Forming Process

Next, a blocking layer 21 is formed on the counter electrode 20 (FIG. 5: Step S10). Similarly to the intermediate layer 18, the blocking layer 21 is formed by forming a film of NaF across all the subpixels by vapor deposition. FIG. 9C illustrates a layered structure after the blocking layer 21 is formed on the counter electrode 20 which is formed on the functional layer 19.

(11) Sealing Layer Forming Process

Next, as illustrated in FIG. 9D, a sealing layer 22 is formed on the blocking layer 21 (FIG. 5: Step S1). The sealing layer 22 is formed by forming a film of SiON, SiN, or the like by sputtering, CVD, or the like. The sealing layer 22 should preferably be formed at a relatively low temperature, for example 80° C. such that the organic light-emitting layers 17, the TFT layer 112, and the like are not damaged.

Thus, the organic EL display panel 10 is completed.

Note that the above-mentioned manufacturing method is just an example pertaining to at least one aspect of the present disclosure, and can be modified as appropriate.

<<Modifications>>

Embodiments of an organic EL display panel, an organic EL display panel manufacturing method, and so on pertaining to at least one aspect of the present disclosure have been described above, but the present disclosure is not limited to the description above beyond essential characteristic elements thereof. The following describes other aspects of the present disclosure as modifications.

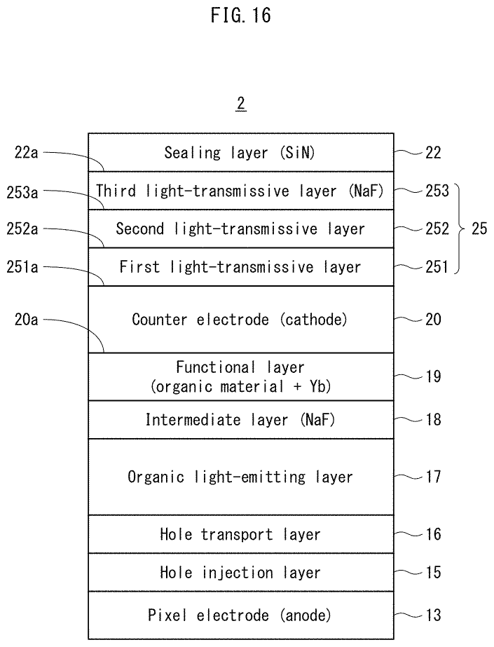

For the simplification purpose, in figures explained below, a layered structure of organic EL elements including every layer from pixel electrodes 13 to a blocking layer 21 is illustrated and a sealing layer 22 disposed above the blocking layer 21 is omitted, with an exception (FIG. 16).

(1) Modifications of Structure of Functional Layer

In at least one embodiment above, the functional layer 19 is a single layer including Yb at a doping concentration which is uniform in the film thickness direction. Alternatively, the following structure may be employed.

(1-1) Functional Layer Having Single Layer Structure with Concentration Gradient of Yb in Film Thickness Direction

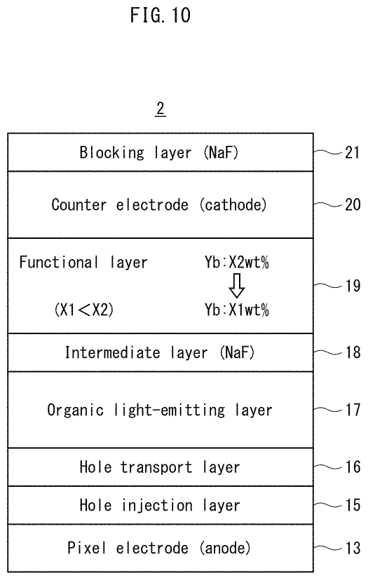

FIG. 10 is a schematic diagram illustrating a layered structure of organic EL elements 2 pertaining to a first modification.

As illustrated in the figure, a doping concentration of Yb included in a functional layer 19 is X2 wt % at a portion in contact with a counter electrode 20, decreases with increasing proximity to the intermediate layer 18, and is X1 wt % (X1<X2) at a portion in contact with the intermediate layer 18.

The doping concentration of Yb included in the functional layer 19 is set to continuously vary in this way. According to this structure, while Yb included in the functional layer 19 exerts a low reduction action of NaF included in the intermediate layer 18 to limit the electron injection properties to a required degree, NaF included in the intermediate layer 18 remains to exhibit waterproofing properties to suppress intrusion of impurities into the functional layer 19. Further, this structure helps to avoid an unnecessary deterioration of the light-transmissivity caused by an increased doping concentration of Yb. In addition, since the doping concentration of Yb in portion of the functional layer 19 nearer the cathode is set to high, the properties of electron injection from the cathode to the functional layer can be improved and also intrusion of external impurities can be prevented, thereby further prolonging the operating life of the organic EL elements.

This helps to provide organic EL elements with a further excellent luminous efficiency and a further prolonged operating life.

Note that examples of methods of gradually varying the doping concentration of Yb include a method using co-deposition according to which respective heating temperatures of Yb and an organic material by an electric furnace are controlled such that a deposition speed of Yb is increased relative to a deposition speed of the organic material.

(1-2) Functional Layer Having Two-Layer Structure

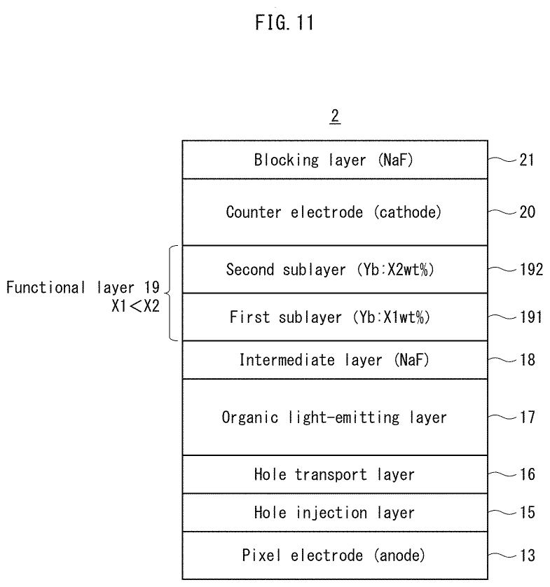

FIG. 11 is a schematic diagram illustrating a layered structure of organic EL elements 2 pertaining to a second modification.

As illustrated in the figure, a functional layer 19 has a two-layer structure including a first sublayer 191 and a second sublayer 192, and the second sublayer 192 includes Yb at a higher doping concentration in wt % (X2) than the first sublayer 191 includes (X1) (X1<X2).

As well as the first modification, the present modification promises an improved luminous efficiency and a prolonged operating life.

(1-3) Functional Layer Having Three-Layer Structure

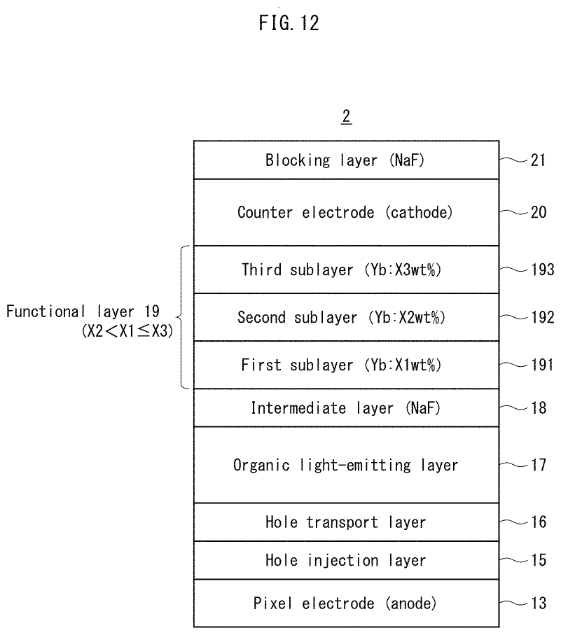

FIG. 12 is a schematic diagram illustrating a layered structure of organic EL elements 2 pertaining to a third modification.

As illustrated in the figure, a functional layer 19 has a three-layer structure including a first sublayer 191, a second sublayer 192, and a third sublayer 193, and a relation X2<X1≤X3 is satisfied, where the first sublayer 191, the second sublayer 192, and the third sublayer 193 respectively include Yb at a doping concentration X1, a doping concentration X2, and a doping concentration X3 in wt %.

In the present modification, the third sublayer 193 nearest a counter electrode 20 includes Yb at a doping concentration equal to or higher than that in the first sublayer 191 nearest an intermediate layer 18. This structure achieves the similar effects to those in the second modification. Also, the second sublayer 192, which is disposed between the first sublayer 191 and the third sublayer 193, includes Yb at the lowest doping concentration among the three sublayers. This structure helps to avoid an unnecessary deterioration of the light-transmissivity since the total doping amount of Yb in the functional layer 19 is not so large. Further, according to this structure, while NaF included in the intermediate layer 18 exhibits waterproofing properties, NaF included in the intermediate layer 18 is reduced by Yb included in the functional layer thereby to improve the properties of electron injection to organic light-emitting layers 17.

Moreover, the increase in doping concentration of Yb in the third sublayer achieves an effect of further improving the properties of electron injection from the cathode to the functional layer and also preventing intrusion of external impurities, thereby further prolonging the operating life of the organic EL elements.

(2) Optical Cavity Structure

In at least one embodiment, an optical cavity structure is adopted to further improve the luminous efficiency.

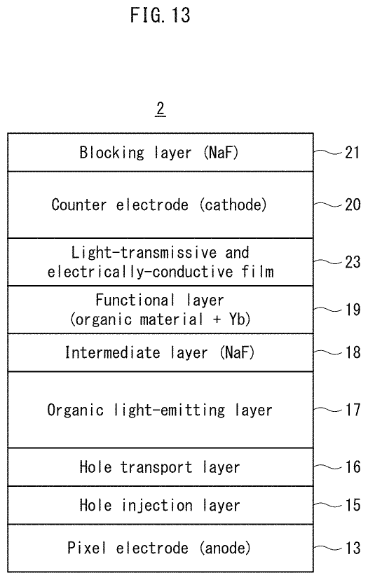

FIG. 13 is a schematic diagram illustrating a layered structure of organic EL elements 2 pertaining to another modification.

As illustrated in the figure, a light-transmissive and electrically-conductive film 23 having a predefined film thickness is disposed between a functional layer 19 and a counter electrode 20. The light-transmissive and electrically-conductive film 23 is formed from ITO, IZO, or the like by for example magnetron sputtering.

By disposing the light-transmissive and electrically-conductive film 23 between the functional layer 19 and the counter electrode 20, a pair of the counter electrode 20 and the light-transmissive and electrically-conductive film 23 functions as a cathode and thus has a decreased sheet resistance in total, thereby contributing to prevention of a luminance deterioration due to a voltage drop of the counter electrode 20. Also, a film thickness of the light-transmissive and electrically-conductive film 23 can be set to relatively large owing to a high light transmissivity of ITO, IZO, and the like. This can be used for an optical path length adjustment for an optical cavity structure.

In at least one embodiment, the light-transmissive and electrically-conductive film 23 has a film thickness of 15 nm or lager. In at least one embodiment, the light-transmissive and electrically-conductive film 23 has a film thickness of 40 nm or lager. By setting the film thickness of the light-transmissive and electrically-conductive film to 15 nm or larger, cavity design (film thickness adjustment for optical cavity structure) can be used effectively, thereby achieving an increased efficiency. Note that the upper limit of the film thickness of the light-transmissive and electrically-conductive film 23 is determined in accordance with design of a desired optical cavity structure.

An optical cavity structure is constructed between interfaces of pixel electrodes 13 to hole injection layers 15 and an interface of the counter electrode 20 to the light-transmissive and electrically-conductive film 23. Especially, to construct a secondary cavity, it is important to adjust an optical length between light emission positions in the organic light-emitting layers 17 (for example, interfaces of the organic light-emitting layers 17 to the hole transport layers 16) and a reflective surface of the counter electrode 20 (the interface of the counter electrode 20 to the light-transmissive and electrically-conductive film 23). Thus, adjustment of the film thickness of the light-transmissive and electrically-conductive film 23 as described above helps to achieve a desired optical cavity.

Note that since Yb is unlikely to react with impurities such as moisture and degrade as described above, the doping amount of Yb in the functional layer 19 can be suppressed to a minimum necessary amount. As a result, the functional layer 19 exhibits a high light-transmissivity and has a film thickness within a wide tolerable range. This widens a tolerable range of the total film thickness of the functional layer 19 and the light-transmissive and electrically-conductive film 23, thereby further increasing a degree of freedom in design of optical cavity structure.

Moreover, also in the case where an ITO film, an IZO film, or the like is formed by sputtering, the functional layer 19 relieves sputtering damages to protect the organic light-emitting layers, thereby achieving organic EL elements with an excellent luminous efficiency and a long-lasting operating life.

(3) Prevention of External Impurity Intrusion and Reduction of Voltage Drop Owing to Decrease in Sheet Resistance of Counter Electrode

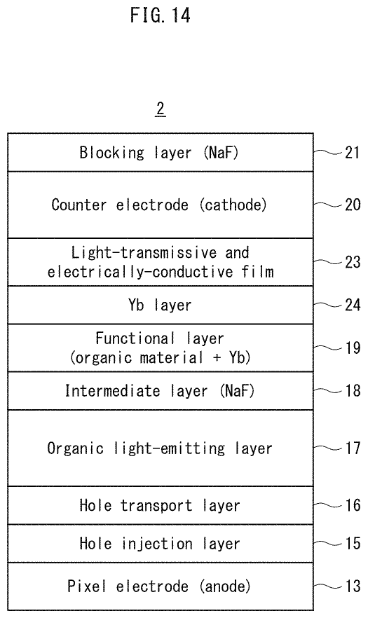

(3-1) FIG. 14 is a schematic diagram illustrating a layered structure of organic EL elements 2 pertaining to another modification.

In the present modification, an intermediate layer 24 including Yb (Yb layer 24) is disposed between a functional layer 19 and a light-transmissive and electrically-conductive film 23. This is a difference from the structure illustrated in FIG. 13.

With this difference, the properties of electron injection from a counter electrode 20 is further improved, and also the Yb layer 24, the light-transmissive and electrically-conductive film 23, and the counter electrode 20 have a decreased sheet resistance in total when they are regarded as one cathode set. This suppresses a voltage drop of the counter electrode 20 in the center on a screen of an organic EL display panel 10 even with an increased size. Thus, a further excellent image quality can be achieved.

Moreover, Yb has a certain level of liquid resistance. Accordingly, the Yb layer 24 prevents impurity intrusion along with its upper layers including a blocking layer 21 and a sealing layer 22, to suppress deterioration of its lower layers including the functional layer 19 and organic light-emitting layers 17, thereby achieving a further prolonged operating life.

In at least one embodiment, the Yb layer 24 has a film thickness of 0.1 nm to 3 nm for the following reasons. With a film thickness smaller than 0.1 nm, the Yb layer 24 cannot sufficiently exhibit an effect of its liquid resistance and decreased sheet resistance. Also, with a film thickness larger than 3 nm, the Yb layer 24 affects adversely light-transmissivity thus to cause a risk of deterioration of the luminous efficiency of the organic EL elements 2 after all.

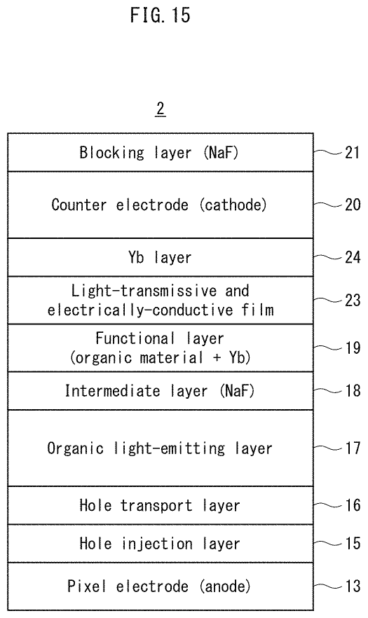

(3-2) FIG. 15 is a schematic Diagram illustrating a layered structure of organic EL elements 2 pertaining to another modification.

In the present modification as illustrated in the figure, a Yb layer 24 is disposed between a light-transmissive and electrically-conductive film 23 and a counter electrode 20. Even with this structure, a pair of the counter electrode 20 and the Yb layer 24 has a decreased sheet resistance, and this suppresses a voltage drop of the counter electrode 20 in the center on a screen of an organic EL display panel 10 even with an increased size. Thus, a further excellent image quality can be achieved.

Also, owing to Yb having a liquid resistance, the Yb layer 24 prevents impurity intrusion from an upper layer (a sealing layer 22) to suppress deterioration of its lower layers including the light-transmissive and electrically-conductive film 23, a functional layer 19, and organic light-emitting layers 17, thereby achieving a prolonged operating life. This structure helps to protect the light-transmissive and electrically-conductive film 23 against external impurities.

In at least one embodiment, the Yb layer 24 in the present modification has a film thickness of 0.1 nm to 3 nm, too, for the same reason as that in the above-mentioned modification in the section (3-1).

As described above, by disposing a single Yb layer between the functional layer 19 and the counter electrode 20, excellent effects can be achieved such as a decrease in sheet resistance of the counter electrode 20, an improvement in impurity blocking properties, and an improvement in electron injection properties.

(3-3) FIG. 16 is a schematic diagram illustrating a layered structure of organic EL elements 2 pertaining to another modification.

In the present modification as illustrated in the figure, a light-transmissive thin film portion 25 is provided outside a counter electrode 20 (on the opposite side of the counter electrode 20 from an organic light-emitting layer 17) by layering light-transmissive films having different refractive indexes. This structure helps to adjust chromaticity of colors of emitted light.

The light-transmissive thin film portion 25 here has a three-layer structure including a first light-transmissive layer 251, a second light-transmissive layer 252, and a third light-transmissive layer 253.

It is a general knowledge that in the case where light-transmissive thin films having different refractive indexes are layered, light enters an interface between each two adjacent light-transmissive thin films and is partially reflected by the interface.

In view of this, in the present modification, as well as an interface 20a between the counter electrode 20 and a functional layer 19, the following interfaces can function as reflective surfaces: an interface 251a between the counter electrode 20 and the first light-transmissive layer 251; an interface 252a between the first light-transmissive layer 251 and the second light-transmissive layer 252; an interface 253a between the second light-transmissive layer 252 and the third light-transmissive layer 253; and an interface 22a between the third light-transmissive layer 253 and a sealing layer 22.

This results in construction of cavities (optical cavity structures) which differ in terms of optical distance (resonant length) from the interface to the reflective surface of the pixel electrodes 13. The cavities generate light of spectra having different peak wavelengths, and light of superposed spectra having peak wavelengths is output from the organic EL elements 2.

Thus, by adjusting the refractive index and the film thickness of each of the layers included in the light-transmissive thin film portion 25 and the counter electrode 20, an effect of making a fine adjustment to chromaticity of output light can be achieved. A peak wavelength of the B, R, or G color is sometimes not ideal, depending on the layered structure including every layer from the pixel electrodes to the counter electrode 20 of the organic EL elements 2, restriction of the film thickness of these layers, or the like. In such a case, the above-mentioned structure is effective for correcting the peak wavelength to be within an ideal wavelength region.

Note that, in the present modification, the first light-transmissive layer 251 includes IZO (refractive index of 2.16 (when wavelength is 450 nm (the same applies below)), the second light-transmissive layer 252 includes SiON (refractive index of 1.66), and the third light-transmissive layer 253 includes NaF (refractive index of 1.34), such that the refractive index differs between each two adjacent layers. Also, the counter electrode 20 includes Ag (refractive index of 0.13). Film thicknesses adjustment to the layers having different refractive indexes helps to increase a color purity of emitted light of a specific color of the R, G, and B colors (in particular the B color).

Since the first light-transmissive layer 251 is a light-transmissive and electrically-conductive IZO film which is disposed on the counter electrode 20 in direct contact with the counter electrode 20, a decreased sheet resistance of the counter electrode 20 suppresses a voltage drop of the counter electrode 20 in the center on a screen of an organic EL display panel 10 even with an increased size. Thus, a further excellent image quality can be achieved. Note that the light-transmissive thin film portion 25 is provided outside the counter electrode 20, and accordingly does not exhibit an effect of reinforcing the electron injection properties. In at least one embodiment, the first light-transmissive layer 251 is a light-transmissive and electrically-conductive film of another material such as ITO.

The material of the second light-transmissive layer 252 is not limited to SiON, and alternatively may be any material which has a refractive index from IZO by a certain level. However, the use of silicon nitride promises a further sealing effect.

The third light-transmissive layer 253 includes NaF and thus can also serve as a blocking layer. Accordingly, even if the sealing layer 22, which is formed at a low temperature, has cracks and impurities intrude through the cracks, the third light-transmissive layer 253 can block the impurities to prevent further intrusion.

In the present modification, the second light-transmissive layer 252 may be omitted. In this case, the first light-transmissive layer 251 and the third light-transmissive layer 253 are layered in direct contact with each other. Although the number of interfaces serving as a reflective surface is smaller by one than the case where the second light-transmissive layer 252 is provided, chromaticity adjustment can be performed because refractive index differs between the first light-transmissive layer 251 and the third light-transmissive layer 253. Also, on the other hand, the light-transmissive thin film portion 25 may include four or more layers. In this case, it is considered that chromaticity adjustment can be performed further finely. However, if an excessively large number of layers are layered, the light-transmissive thin film portion 25 has a large film thickness in total. In view of this, the number of layers should preferably be set so as not to deteriorate the light-transmissivity and thus the light-extraction efficiency.

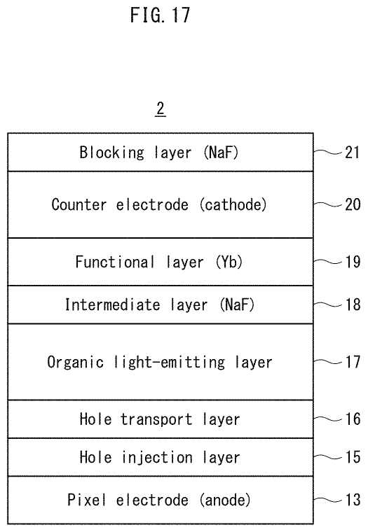

(3-4) FIG. 17 is a Schematic Diagram Illustrating a Layered Structure of Organic EL Elements 2 Pertaining to Another Modification.

In at least one embodiment, the functional layer 19 is formed by doping an organic material with Yb (see FIG. 4A), but the present disclosure is not limited to this. The functional layer 19 may be a single Yb layer as illustrated in FIG. 17.

Organic materials have properties of absorbing a relatively large amount of moisture and the like. In the present modification, in view of this, the functional layer 19 is a single Yb layer having a high stability. Compared with a functional layer including an organic material doped with Yb, the single Yb layer has a further increased liquid resistance and also has an increased Yb effective contact area with NaF of the intermediate layer 18. This promotes a reduction action of NaF by Yb, thereby helping to Na obtained by dissociation to improve the electron injection properties.

In this case, the functional layer 19 is formed by forming a Yb film on the intermediate layer 18 by vapor deposition or sputtering.

In at least one embodiment, the single Yb film has a film thickness of 0.1 nm to 10 nm for the following reason. With a film thickness smaller than 0.1 nm, the single Yb layer might exhibit insufficient electron injection properties. Also, with a film thickness larger than 10 nm, the single Yb layer causes a problem in light-transmissivity and thus might exhibit a deteriorated luminous efficiency.

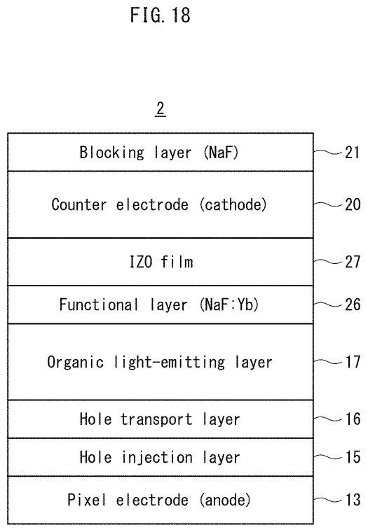

(3-5) FIG. 18 is a Schematic Diagram Illustrating a Layered Structure of Organic EL Elements 2 Pertaining to Another Modification.

In the present modification as illustrated in the figure, an intermediate layer 18 is not provided and a functional layer 26 includes a mixture of NaF and Yb.

This functional layer 26 is formed by for example co-deposition of NaF and Yb on organic light-emitting layers 17.

With this structure, the functional layer 26 itself has both electron injection properties exhibited by Yb and properties of blocking impurities such as moisture which are the inherent function of the intermediate layer 18, and atoms of NaF and Yb are mixed together dispersedly in one layer, thereby achieving effects as follows.

Specifically, such as in the modification illustrated in FIG. 17 where the functional layer 19 (single Yb layer) is layered on the intermediate layer 18 (NaF), a reduction action of NaF by Yb exerts on only a contact portion of the intermediate layer 18 which is in contact with the functional layer 19. Accordingly, an increase in film thickness of the intermediate layer 18 further boosts an increase in driving voltage. Thus, the purpose of improving the luminous efficiency might be insufficiently achieved.

According to the present modification, however, since the single functional layer 26 includes NaF and Yb which mixed together by co-deposition, reduction of NaF by Yb exerts on even an inner portion of the layer. Accordingly, even when the film thickness of the functional layer 26 is increased to a certain extent, the electron injection properties are unlikely to deteriorate, and thus the functional layer 26 can serve as a layer for adjusting an optical distance in an optical cavity structure. This eliminates the need to provide any other special film thickness adjustment layer, thereby simplifying the manufacturing process to reduce the production cost, and also constructing the optical cavity structure to achieve an improvement in luminous efficiency.

In the present modification, a preferable ratio (wt %) of a weight of Yb to a total weight of NaF and Yb is larger than 73 wt % and smaller than 100 wt %, and a preferable film thickness of the functional layer 26 is 10 nm or larger and smaller than 20 nm.

Moreover, in the present modification, an IZO film 27 is disposed on the functional layer 26 so as to be in contact with the functional layer 26.

Rare earth metals such as Yb typically have the following characteristics. When a rare earth metal is oxidized, light-transmissivity is improved. Meanwhile, when a single rare earth metal is oxidized, an oxide (passivity) is formed on only a surface of the single rare earth metal. Due to blocking by the oxide, which is formed densely on the rare earth metal, Yb atoms in a further inner portion of a layer is not oxidized. According to the present modification, however, since NaF and Yb are co-deposited and Yb atoms and NaF molecules are dispersedly present as a mixture, the Yb atoms (Yb clusters) have gaps therebetween. By sputtering IZO on the mixture, not only the Yb atoms on the surface are oxidized, but also IZO intrudes through the gaps between the Yb atoms and thus the Yb atoms in the inside are successively oxidized. This helps to oxidization of even Yb atoms which are present at a significantly depth in the film thickness direction, thereby achieving an effect of a remarkably improved transmittance.

In at least one embodiment, a light-transmissive and electrically-conductive film including another inorganic oxide (for example, an ITO film) is disposed, instead of the IZO film 27.

(4) Materials of Intermediate Layer and Blocking Layer and Metal Dopant of Functional Layer

(4-1) The material of the intermediate layer 18 is not limited to NaF, and only needs to be a fluoride of a metal (first metal) selected from alkali metals or alkaline earth metals. This is because such a fluoride of the first metal has the following common features of: having a high light transmittance; being unlikely to allow intrusion of impurities such as moisture; and exhibiting electron injection properties by reduction of the first metal.

In fact, while many of fluorides of alkali metals and the like are difficult to dissolve in water, NaF is water-soluble. Accordingly, NaF exhibits a high hygroscopic effect and exerts an action of absorbing and keeping thereinside moisture which has intruded from the lower layers, such that the moisture does not remain in lower layers as well as in the intermediate layer. In view of this, it is considered that NaF also can contribute to prevention of deterioration of the functions of the lower layers and thus is more excellent than fluorides of other metals also in terms of this point.

(4-2) In at least one embodiment above, the intermediate layer 18 and the blocking layer 21 include a fluoride of the same metal. Alternatively, the intermediate layer 18 and the blocking layer 21 may each include a fluoride of a different metal (for example, NaF and LiF). However, the use of the same material allows the use of the same vapor deposition mask and the same vapor deposition apparatus, thereby exhibiting a great cost advantage.

(4-3) In at least one embodiment above, Yb is used as the metal dopant of the functional layer 19. Alternatively, other rare earth metal may be used as the metal dopant of the functional layer 19 because of having features substantially common to Yb such as a low work function, a light-transmissivity, a liquid resistance, reducing properties, and so on.

Alternatively, the metal dopant of the functional layer 19 may be an alkali metal or an alkaline earth metal similar to conventional ones in some cases. Alkali metals and the like have a high reactivity with impurities such as moisture compared with rare earth metals as described above. In at least one aspect of the present disclosure above, the functional layer 19 is sandwiched between the intermediate layer 18 and the blocking layer 21. This structure helps to block impurities intruding from the organic light-emitting layers 17 and layers thereunder formed by an application method and also to block impurities intruding through cracks of the sealing layer 22. Accordingly, even when using an alkali metal or the like as the metal dopant of the functional layer 19, the operating life can be prolonged at least compared with a conventional structure in which no blocking layer is provided. For this reason, an alkali metal or the like can be used as the metal dopant of the functional layer 19.

(5) Other Modifications of Layered Structure of Organic EL Elements

In at least one embodiment above, the organic EL elements have the layered structure including the hole injection layers 15, the hole transport layers 16, the organic light-emitting layers 17, the intermediate layer 18, and the functional layer 19. However, the present disclosure is not limited to this. Alternatively, the organic EL elements for example may include an electron injection layer between the counter electrode 20 and the functional layer 19.

Also, the organic EL elements for example do not need to include the hole transport layers 16. Furthermore, the organic EL elements for example may include hole injection transport layers which are single layers, instead of the hole injection layers 15 and the hole transport layers 16.

Note that a pair of the hole injection layers and the hole transport layers, or the hole injection transport layers can be defined as hole transfer facilitating layers in a sense of facilitating hole transfer from the anodes to the organic light-emitting layers. The present disclosure can further enjoy an effect exhibited by the impurity blocking structure, in the case where at least one type of the organic light-emitting layers and the hole transfer facilitating layers is formed by a wet process such as a printing method.

(6) Formation Range of Blocking Layer

The blocking layer 21 is disposed across all the organic EL elements, similarly to the intermediate layer 18, the functional layer 19, the counter electrode 20, and the sealing layer 22.

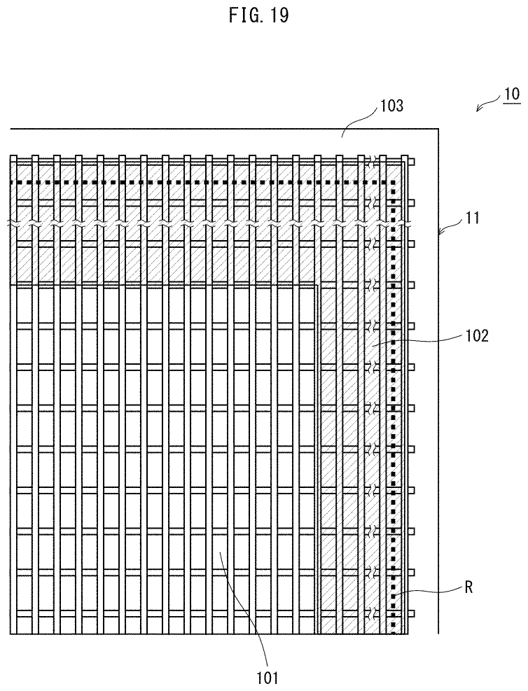

FIG. 19 is an enlarged plan view schematically illustrating an upper right corner portion of the organic EL display panel 10. The substrate 11, on which the subpixels are arranged in a matrix, has an image display region 101 in the center and a non-display region 102 around the image display region 101. In the non-display region 102, dummy pixels are arranged.

A dashed line R indicates a position of the edge of the blocking layer 21. The blocking layer 21 is disposed in the whole range surrounded by the dashed line R. From the viewpoint of sealing properties, the blocking layer 21 should preferably cover the whole image display region 101 in this way, but does not need to wholly cover the non-display region 102, which does not contribute to light emission, and only needs to partially cover the non-display region 102 in the periphery of the image display region 101. Also, the blocking layer 21 should preferably not be disposed in a peripheral portion (frame portion) 103 on the substrate 11 where electrodes and so on are to be disposed.

Note that in the case where the intermediate layer 18, the functional layer 19, the counter electrode 20, the sealing layer 22, and the like are all disposed in the same range where the blocking layer 21 is disposed, a metal mask and the like for forming these layers are used in common. This is a great manufacturing cost advantage.

(7) According to the organic EL display panel 10 pertaining to at least one embodiment above, as illustrated in FIG. 2, the pixel partition layers 141 extend in the long-axis X direction of the organic EL display panel 10 and the banks 14 extend in the short-axis Y direction of the organic EL display panel 10. However, the present disclosure is not limited to this. The extending directions of the pixel partition layers 141 and the banks 14 may be reversed. Alternatively, the extending directions of the pixel partition layers 141 and the banks 14 may be directions independent of the shape of the organic EL display panel 10.

Also, according to the organic EL display panel 10 pertaining to at least one embodiment above, the image display surface has a rectangular shape as an example. However, the present disclosure is not limited to this. Any appropriate modification is possible.

Further, according to the organic EL display panel 10 pertaining to at least one embodiment above, the pixel electrodes 13 are rectangular plate-like members. However, the present disclosure is not limited to this.

Moreover, in at least one embodiment above, the description has been provided on an organic EL display panel employing the line bank structure. However, the present disclosure is not limited to this and may be an organic EL display panel employing a so-called pixel bank structure in which all sides of each subpixel are surrounded by banks. However, when the line bank structure is employed, an effect of adopting Yb which is resistant to impurities as a metal dopant of the functional layer 19 is exhibited further greatly, compared with the pixel bank structure. This is because according to the line bank structure, applied films such as the light-emitting layers 17 are disposed even on the pixel partition layers 141 and thus a larger amount of ink is dropped and a larger amount of moisture etc. remains after drying, compared with the pixel bank structure.

(8) In the organic EL display panel 10 pertaining to at least one embodiment above, the subpixels 100R, 100G, and 100B, which emit light of the R, G, and B colors respectively, are arranged. However, the light emission colors of the subpixels are not limited to these and may be for example four colors including yellow (Y) color in addition to the R, G, and B colors. Also, the number of subpixels per color arranged in one pixel P is not limited to one, and may be plural. Further, the arrangement order of the subpixels in each pixel P is not limited to the red, green, and blue colors such as illustrated in FIG. 2, and the subpixels may be reordered among these colors.

(9) In FIG. 3 and the like pertaining to at least one embodiment above, an example is disclosed in which the film thicknesses of the layers of the organic EL elements are uniform among the light emission colors. In the case where an optical cavity structure is constructed in practice, for example optical distances (A) to (C) below are determined by a known optical design depending on the wavelength of each of the light emission colors: (A) an optical distance from the reflective surface of the pixel electrode 13 to the reflective surface of the counter electrode 20; (B) an optical distance from the reflective surfaces of the pixel electrodes 13 to the interfaces between the hole transport layers 16 and the organic light-emitting layers 17; and (C) an optical distance from the interfaces between the hole transport layers 16 and the organic light-emitting layers 17 to the reflective surface of the counter electrode 20. Accordingly, for example, the film thicknesses of the hole transport layers 16, the organic light-emitting layers 17, the functional layer 19, the light-transmissive and electrically-conductive film 23, and the like are adjusted in accordance with these determined distances.

Note that an optical cavity structure does not need to be adopted for all of the light emission colors. Also, one pixel can include light-emitting elements of the same light emission color. Thus, a layered structure of a display panel having such a structure is summarized by the following expression:

“A display panel in which pixels each including light-emitting parts are two-dimensionally arranged across a main surface of a substrate, wherein with respect to each of the pixels, at least one of the light-emitting parts differs from any other of the light-emitting parts in terms of light emission color, and the at least one light-emitting part differs from the any other of the light-emitting parts in terms of film thickness of at least one of the light-emitting layer and the first functional layer.”.

(10) Further, in at least one embodiment above, the organic EL display panel 10 employs the active matrix system. However, the present disclosure is not limited to this, and a passive matrix system may be employed. Moreover, the present disclosure is applicable not only to organic EL display panels of the top-emission type but also to organic EL display panels of a bottom-emission type.

(11) In at least one embodiment above, description has been provided on an organic EL display panel in which organic EL light-emitting layers are used. In addition to such an organic EL display panel, display panels such as quantum dot display panels including QLEDs as light-emitting layers (see for example Japanese Patent Application Publication No. 2010-199067) have a structure similar to organic EL display panels in which light-emitting layers and other functional layers are disposed between pixel electrodes and a counter electrode, except only structures and types of the light-emitting layers. Accordingly, the present disclosure is applicable to formation of such display panels when an application method is used for forming light-emitting layers and other functional layers.

### SUPPLEMENT

Description has been provided above of display panels and display panel manufacturing methods pertaining to the present disclosure based on embodiments and modifications, but the present disclosure is not limited to the embodiments and modifications described above. Although one or more embodiments pertaining to the present disclosure have been fully described by way of examples with reference to the accompanying drawings, it is to be noted that various changes and modifications will be apparent to those skilled in the art. Therefore, unless such changes and modifications depart from the scope of the present disclosure, they should be construed as being included therein.

1. A display panel comprising:
a substrate;
anodes that are two-dimensionally disposed on or above the substrate;
light-emitting layers that are disposed on or above the anodes in correspondence with the respective anodes;
an intermediate layer that is disposed on or above the light-emitting layers and includes a fluoride of a first metal selected from alkali metals or alkaline earth metals;
a functional layer that is disposed on the intermediate layer and includes a second metal selected from alkaline earth metals or rare earth metals;
a cathode that is disposed on or above the functional layer;
a blocking layer that is disposed on or above the cathode and includes a fluoride of a third metal selected from alkali metals or alkaline earth metals; and
a sealing layer that is disposed on or above the blocking layer.

2. The display panel of claim 1, wherein
the intermediate layer has a film thickness of 0.1 nm to 20 nm.

3. The display panel of claim 1, wherein
the blocking layer has a film thickness of 0.1 nm to 100 nm.

4. The display panel of claim 1, wherein
the first metal is sodium (Na).

5. The display panel of claim 1, wherein
the third metal is sodium (Na).

6. The display panel of claim 1, wherein
the second metal is a rare earth metal.

7. The display panel of claim 6, wherein
the rare earth metal is ytterbium (Yb).

8. The display panel of claim 6, wherein
the functional layer is a single layer of the rare earth metal.

9. The display panel of claim 6, wherein
the functional layer includes an organic material doped with the rare earth metal.

10. The display panel of claim 9, wherein
a doping concentration of the rare earth metal in the functional layer is 3 wt % to 60 wt %.

11. The display panel of claim 10, wherein
the functional layer has a film thickness of 5 nm to 150 nm.

12. The display panel of claim 9, wherein
a doping concentration of the rare earth metal included in the functional layer continuously increases with increasing proximity to the cathode.

13. The display panel of claim 9, wherein
the functional layer includes a first sublayer that is disposed on the intermediate layer and a second sublayer that is disposed on the first sublayer, and
the second sublayer includes the rare earth metal at a higher doping concentration than the first sublayer includes.

14. The display panel of claim 9, wherein
the functional layer includes a first sublayer, a second sublayer, and a third sublayer that are layered in this order on the intermediate layer, and
a relation X2<X1≤X3 is satisfied, where the first sublayer, the second sublayer, and the third sublayer respectively include the rare earth metal at a doping concentration X1, a doping concentration X2, and a doping concentration X3.

15. The display panel of claim 1, further comprising:
a light-transmissive and electrically-conductive film that is disposed between the functional layer and the cathode.

16. The display panel of claim 15, wherein
the light-transmissive and electrically-conductive film has a film thickness of 15 nm or larger.

17. The display panel of claim 15, further comprising:
a thin film that is disposed between the functional layer and the light-transmissive and electrically-conductive film, includes a rare earth metal, and has a film thickness of 0.1 nm to 3 nm.

18. The display panel of claim 15, further comprising:
a thin film that is disposed between the light-transmissive and electrically-conductive film and the cathode, includes a rare earth metal, and has a film thickness of 0.1 nm to 3 nm.

19. A display panel comprising:
a substrate;
anodes on or above the substrate so as to be two-dimensionally disposed;
light-emitting layers on or above the anodes in correspondence with the respective anodes;
a functional layer that is disposed on or above the light-emitting layers and includes a mixture of a fluoride of a first metal selected from alkali metals or alkaline earth metals and a second metal selected from rare earth metals;
a cathode that is disposed on or above the functional layer;
a blocking layer that is disposed on or above the cathode and includes a fluoride of a third metal selected from alkali metals or alkaline earth metals; and
a sealing layer that is disposed on or above the blocking layer.

20. The display panel of claim 19, wherein
the first metal and the third metal are each sodium (Na), and the second metal is ytterbium (Yb).

21. The display panel of claim 19, further comprising:
a light-transmissive and electrically-conductive film that is disposed between the functional layer and the cathode so as to be in contact with the functional layer, and includes an inorganic oxide.

22. The display panel of claim 1, being of a top-emission type.

23. A method of manufacturing a display panel, the method comprising:
preparing a substrate:
forming anodes that are two-dimensionally disposed on or above the substrate;
forming light-emitting layers on or above the anodes in correspondence with the respective anodes;
forming an intermediate layer on or above the light-emitting layers, the intermediate layer including a fluoride of a first metal selected from alkali metals or alkaline earth metals;
forming a functional layer on the intermediate layer, the functional layer including a second metal selected from alkaline earth metals or rare earth metals;
forming a cathode on or above the functional layer;
forming a blocking layer on or above the cathode, the blocking layer including a fluoride of a third metal selected from alkali metals or alkaline earth metals; and
forming a sealing layer on or above the blocking layer.

24. A method of manufacturing a display panel, the method comprising:
preparing a substrate:
forming anodes that are two-dimensionally disposed on or above the substrate;
forming light-emitting layers on or above the anodes in correspondence with the respective anodes;
forming a functional layer on or above the light-emitting layers, the functional layer including a mixture of a fluoride of a first metal selected from alkali metals or alkaline earth metals and a second metal selected from rare earth metals;
forming a cathode on or above the functional layer;
forming a blocking layer on or above the cathode, the blocking layer including a fluoride of a third metal selected from alkali metals or alkaline earth metals; and
forming a sealing layer on or above the blocking layer.

25. The method of claim 23, further comprising:
between the forming the anodes and the forming the light-emitting layers, forming hole transfer facilitating layers that have at least one of hole injection properties and hole transport properties, wherein
at least one type of the hole transfer facilitating layers and the light-emitting layers is formed by a wet process.

26. The method of claim 24, further comprising:
between the forming the anodes and the forming the light-emitting layers, forming hole transfer facilitating layers that have at least one of hole injection properties and hole transport properties, wherein
at least one type of the hole transfer facilitating layers and the light-emitting layers is formed by a wet process.
